(19) United States
(12) Patent Application Publication
(10) Pub. No.: US 2025/0022791 A1
(43) Pub. Date: Jan. 16, 2025

(54) SEMICONDUCTOR DEVICE

(71) Applicant: Flosfia Inc., Kyoto (JP)

(72) Inventors: Hiroshi KONDO, Kyoto (JP); Tatsuhiro NAKAZAWA, Kyoto (JP); Kengo TAKEUCHI, Kyoto (JP); Takashi SHINOHE, Kyoto (JP)

(21) Appl. No.: 18/901,920

(22) Filed: Sep. 30, 2024

Related U.S. Application Data
(63) Continuation-in-part of application No. PCT/JP2023/013116, filed on Mar. 30, 2023.

(30) Foreign Application Priority Data
Mar. 31, 2022 (JP) 2022-061092
Mar. 31, 2022 (JP) 2022-061093
Mar. 31, 2022 (JP) 2022-061094

(51) Int. Cl. H01L 23/498

(52) U.S. Cl. CPC H01L 23/49844; H01L 23/49861

(57) ABSTRACT

Provided is a semiconductor device including: a first wiring layer; a holding layer; a semiconductor element that is disposed between the first wiring layer and the holding layer and includes at least a semiconductor layer and a first electrode disposed on a first surface of the semiconductor layer; an insulator in which at least a part of the semiconductor element is embedded; and a first connecting portion that electrically connects the first wiring layer and the first electrode, wherein a connection area between the first connecting portion and the first electrode occupies 45% or more of an area of an exposed part of the first electrode.

### CROSS REFERENCE TO RELATED APPLICATION

This application is a bypass continuation-in-part application of International Patent Application No. PCT/JP2023/013116 (Filed on Mar. 30, 2023), which claims the benefit of priority from Japanese Patent Application No. 2022-061092, 2022-061093, 2022-061094 (filed on Mar. 31, 2022).

The entire contents of the above applications, which the present application is based on, are incorporated herein by reference.

### 1. FIELD OF THE INVENTION

The present disclosure relates to a semiconductor device with a semiconductor element embedded in an insulator.

### 2. DESCRIPTION OF THE RELATED ART

In recent years, a module using a print circuit substrate as a core and including a semiconductor element embedded in an insulating layer has been studied. It is known that a multilayer wiring substrate which is a wiring substrate including: a wiring substrate that includes a wiring layer and an insulating layer stacked therein; an electronic component that includes a plurality of electrodes aligned at a predetermined pitch and bumps formed on the plurality of electrodes; and lands that are for connecting the bumps and wiring in an upper layer circuit, each of the plurality of bumps including a flat surface on its upper portion, each flat surface being connected directly to the plurality of lands. It is known that an electronic component incorporated substrate including: a resin substrate; a semiconductor device that is placed on a surface of the resin substrate with a rear surface thereof facing the resin substrate; an insulating layer that covers the semiconductor device; at least one via conductor that is embedded inside the insulating layer; and a wiring pattern that is electrically connected to any of the via conductors, the semiconductor device including an electric circuit and at least one terminal that is exposed in an principal plane and is electrically connected to the electric circuit, both a non-terminal region where at least one first terminal is not exposed in the principal plane and the rear surface being roughened.

Note that, in the section of the background art, embodiments of the present disclosure are provided in context of technologies and actions in order to give support to those skilled in the art to understand the scope and usefulness of the present disclosure. The description in the present specification should not be regarded as a prior art merely by being included in the section of the background art unless otherwise explicitly specified.

### SUMMARY OF THE INVENTION

A summary that simplifies the present disclosure will be presented below to provide basic understanding to those skilled in the art. The summary is not intended to specify important elements of embodiments of the present disclosure or to define the scope of the present disclosure. A purpose of the summary of the disclosure is to present several concepts disclosed in the specification in a simplified form as introduction of more detailed description presented later.

According to an example of the present disclosure, there is provided a semiconductor device including: a first wiring layer; a holding layer; a semiconductor element that is disposed between the first wiring layer and the holding layer and includes at least a semiconductor layer and a first electrode disposed on a first surface of the semiconductor layer; an insulator in which at least a part of the semiconductor element is embedded; and a first connecting portion that electrically connects the first wiring layer and the first electrode, wherein a connection area between the first connecting portion and the first electrode occupies 45% or more of an area of an exposed part of the first electrode.

According to an example of the present disclosure, there is provided a semiconductor device including: a first wiring layer; a holding layer; a semiconductor element that is disposed between the first wiring layer and the holding layer and includes at least a semiconductor layer and a first electrode disposed on a first surface of the semiconductor layer; an insulator in which at least a part of the semiconductor element is embedded; and a first connecting portion that electrically connects the first wiring layer and the first electrode, wherein in a plan view, an outer periphery of the first electrode includes a first straight portion, an outer periphery of the first connecting portion includes a second straight portion, and the first straight portion and the second straight portion are parallel or substantially parallel to each other.

According to an example of the present disclosure, there is provided a semiconductor device including: a first wiring layer; a holding layer; a semiconductor element that is disposed between the first wiring layer and the holding layer and includes a semiconductor layer and a first electrode disposed on a first surface of the semiconductor layer; and a first connecting portion that is in contact with an exposed part of the first electrode and electrically connects the first wiring layer and the first electrode, wherein in a plan view, a shortest distance between the first connecting portion and an end portion of the exposed part is less than 50 μm.

According to an example of the present disclosure, there is provided a semiconductor device including: a first wiring layer; a holding layer; a semiconductor element that is disposed between the first wiring layer and the holding layer; and an insulator in which at least a part of the semiconductor element is embedded, wherein the holding layer includes a projecting portion that is located immediately below the semiconductor element and is at least partially buried in the insulator.

Thus, it is possible to provide a semiconductor device with improved heat dissipation and/or electrical connectivity.

### BRIEF DESCRIPTION OF THE DRAWINGS

FIG. 1 is a schematic sectional view of a semiconductor device according to one embodiment of the present disclosure.

FIG. 2A is a sectional view for explaining a method of manufacturing a semiconductor device according to one embodiment of the present disclosure.

FIG. 2B is a sectional view for explaining a method of manufacturing a semiconductor device according to one embodiment of the present disclosure.

FIG. 2C is a sectional view for explaining a method of manufacturing a semiconductor device according to one embodiment of the present disclosure.

FIG. 2D is a sectional view for explaining a method of manufacturing a semiconductor device according to one embodiment of the present disclosure.

FIG. 2E is a sectional view for explaining a method of manufacturing a semiconductor device according to one embodiment of the present disclosure.

FIG. 2F is a sectional view for explaining a method of manufacturing a semiconductor device according to one embodiment of the present disclosure.

FIG. 2G is a sectional view for explaining a method of manufacturing a semiconductor device according to one embodiment of the present disclosure.

FIG. 3 is a schematic sectional view of a semiconductor device according to one embodiment of the present disclosure.

FIG. 4A is a sectional view for explaining a method of manufacturing a semiconductor device according to one embodiment of the present disclosure.

FIG. 4B is a sectional view for explaining a method of manufacturing a semiconductor device according to one embodiment of the present disclosure.

FIG. 4C is a sectional view for explaining a method of manufacturing a semiconductor device according to one embodiment of the present disclosure.

FIG. 4D is a sectional view for explaining a method of manufacturing a semiconductor device according to one embodiment of the present disclosure.

FIG. 4E is a sectional view for explaining a method of manufacturing a semiconductor device according to one embodiment of the present disclosure.

FIG. 5 is a block diagram illustrating an example of a control system applying the semiconductor device according to an embodiment of the disclosure.

FIG. 6 is a circuit diagram illustrating an example of the control system applying the semiconductor device according to an embodiment of the disclosure.

FIG. 7 is a block configuration diagram illustrating another example of the control system applying the semiconductor device according to an embodiment of the disclosure.

FIG. 8 is a circuit diagram illustrating another example of the control system applying the semiconductor device according to an embodiment of the disclosure.

FIG. 9 is a schematic plan view for explaining a connection area in a reference example.

FIG. 10A is a schematic plan view for explaining an example of a relationship of a connecting portion, an insulating film, and an electrode in a semiconductor device according to an embodiment of the present disclosure.

FIG. 10B is a schematic plan view for explaining another example of the relationship of the connecting portion, the insulating film, and the electrode in the semiconductor device according to the embodiment of the present disclosure.

FIG. 11 is a schematic plan view for explaining a linear portion of the semiconductor device according to the embodiment of the present disclosure.

### DETAILED DESCRIPTION

Aspects of the present disclosure, and their various features and favorable details will be described and/or illustrated using the drawings and will be specifically described with reference to non-limited aspects and examples described in the following specification. As is obvious for those skilled in the art, features illustrated in the drawings are not necessarily depicted at a specific scale even if no description is given in the specification. Also, it should be noted that one feature in one aspect may also be used alone or in combination with another feature in another aspect. Description of known elements and working technologies may be omitted in order to prevent the aspects of the present disclosure from becoming unnecessarily unclear. Examples used in the specification are to simply help understanding of the present disclosure and also to enable those skilled in the art to implement the aspects of the present disclosure. Therefore, the aspects and the examples in the specification are not to be interpreted as being limited to the scope of the present disclosure and are defined merely by the scope of the claims and the applicable law. Furthermore, similar parts are denoted by similar reference signs in the drawings of the present disclosure.

Although terms such as “first” and “second” will be used to describe various elements used in the specification, the elements are not limited to these terms. The terms such as “first” and “second” are used merely to distinguish one element from another element. For example, a first element may be referred to as a second element, and a second element may be referred to as a first element without departing from the scope of the present disclosure. As is used in the specification, the term “and/or” includes one item of or a combination of some or all of a plurality of items of listed items.

In the present disclosure, a direction that is parallel to a depth direction of a first wiring layer is defined as an “up-down direction”. Also, a direction from a holding layer toward the first wiring layer is defined as an “upper side”, and a direction from the first wiring layer toward the holding layer is defined as a “lower side”. The present disclosure will be described on the assumption that a surface located on the upper side out of two principal planes of a layer, a substrate, or another member is an upper surface and a surface located on the lower side is a lower surface. These “upward” and “downward” directions are not limited to a direction of gravity or a direction of attachment to a substrate or the like when a semiconductor device is mounted.

It should be understood that in a case where an expression that an element such as a layer, a region, or a substrate is present “above” another element or extends “upward” is used, the element may be present directly on another element or the element may extend directly upward, or an intervening element may be present. On the other hand, in a case where an expression that an element is present “directly on” another element or extends “directly upward” is used, an intervening element is not present. Similarly, it should be understood that in a case where an expression that an element such as a layer, a region, or a substrate is “across” another element or extends “across” another element is used, the element may be directly across another element or the element may extend directly across another element, or an intervening element may be present. On the other hand, in a case where an expression that an element is “directly across” another element or extends “directly across” another element is used, an intervening element is not present. It should be understood that in a case where an expression that an element is “connected to” or “coupled to” another element is used, the element may be connected or coupled directly to another element, or an intervening element may be present. On the other hand, in a case where an expression that an element is “connected directly to” or “coupled directly to” another element is used, an intervening element is not present.

Terms used in the specification are to describe only specific aspects and are not intended to limit the present disclosure. “Comprise” and “include” used in the specification represent presence of described elements and do not exclude presence of another element or a plurality of other elements.

All the terms (including technical terms and scientific terms) used in the specification have the same meanings as those typically understood by those skilled in the technical field to which the present disclosure belongs unless otherwise defined. The terms used in the specification are to be interpreted as having means that do not conflict with the context of the specification and meaning in the related art. Also, it should be understood that the terms used in the specification are not to be interpreted as idealized meanings or excessively formal meaning unless defined in the specification.

A semiconductor device according to the present disclosure includes: a first wiring layer; a holding layer; a semiconductor element that is disposed between the first wiring layer and the holding layer and includes at least a semiconductor layer and a first electrode disposed on a first surface of the semiconductor layer; an insulator in which at least a part of the semiconductor element is embedded; and a first connecting portion that electrically connects the first wiring layer and the first electrode, and a connection area between the first connecting portion and the first electrode occupies 45% or more of an area of an exposed part of the first electrode. Note that the “connection area” means an area in which the first connecting portion and the first electrode are connected to each other in a plan view. Also, the area of the exposed part means an area of a part of a surface of the first electrode that is exposed from an insulating film and is able to establish electrical connection in a plan view.

Also, a semiconductor device according to the present disclosure includes: a first wiring layer; a holding layer; a semiconductor element that is disposed between the first wiring layer and the holding layer and includes at least a semiconductor layer and a first electrode disposed on a first surface of the semiconductor layer; an insulator in which at least a part of the semiconductor element is embedded; and a first connecting portion that electrically connects the first wiring layer and the first electrode, and in a plan view, an outer periphery of the first electrode includes a first straight portion, an outer periphery of the first connecting portion includes a second straight portion, and the first straight portion and the second straight portion are parallel or substantially parallel to each other.

Also, a semiconductor device according to the present disclosure includes: a first wiring layer; a holding layer; a semiconductor element that is disposed between the first wiring layer and the holding layer and includes a semiconductor layer and a first electrode disposed on a first surface of the semiconductor layer; and a first connecting portion that is in contact with an exposed part of the first electrode and electrically connects the first wiring layer and the first electrode, and a shortest distance between the first connecting portion and an end portion of the exposed part is less than 50 μm in a plan view.

Also, a semiconductor device according to the present disclosure includes: a first wiring layer; a holding layer; a semiconductor element that is disposed between the first wiring layer and the holding layer; and an insulator in which at least a part of the semiconductor element is embedded, and the holding layer includes a projecting portion that is located immediately below the semiconductor element and is at least partially buried in the insulator.

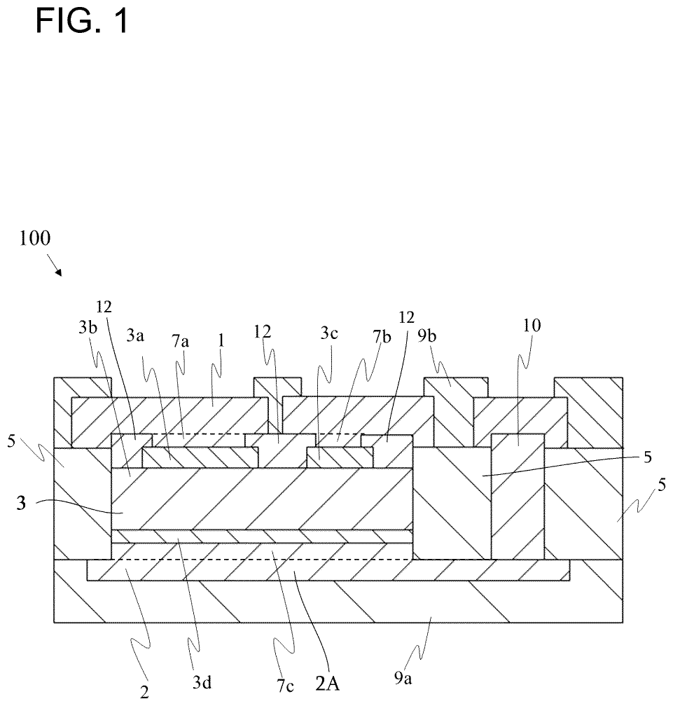

FIG. 1 is a sectional view schematically illustrating a semiconductor device according to one embodiment of the present disclosure. A semiconductor device 100 in FIG. 1 includes a semiconductor element 3 (hereinafter, a semiconductor layer 3b, a first electrode 3a, a second electrode 3c, and a third electrode 3d will also collectively be referred to as a semiconductor element 3) disposed between a first wiring layer 1 and a holding layer 2A and an insulator 5 in which at least a part of the semiconductor element 3 is embedded. The semiconductor device 100 in FIG. 1 has a configuration in which the first wiring layer 1 constitutes an upper wiring layer and the first wiring layer 1 is electrically split into at least two or more parts in a horizontal plane. The first electrode 3a in the semiconductor element 3 is electrically connected to the first wiring layer 1 via a first connecting portion 7a. The second electrode 3c in the semiconductor element 3 is electrically connected to the first wiring layer 1 via a second connecting portion 7b. The holding layer 2A may further includes a second wiring layer (lower wiring layer) and a third connecting portion 7c. In the embodiment, the third electrode 3d in the semiconductor element 3 is electrically connected to the second wiring layer 2 via the third connecting portion 7c. Also, the first wiring layer 1 and the second wiring layer 2 are electrically connected to each other via a metal block 10.

The semiconductor element 3 is, for example, a metal oxide film semiconductor field effect transistor (MOSFET) and includes the semiconductor layer 3b, a source electrode 3a and a gate electrode 3c that are provided on the side of a first surface of the semiconductor layer 3b, and a drain electrode 3d that is provided on a side of a second surface of the semiconductor layer 3b on the side opposite to the first surface. The first semiconductor element 3 is not limited to the MOSFET and may be, for example, an insulating gate bipolar transistor (IGBT). In the case where the first semiconductor element 3 is an IGBT, the first semiconductor element 3 includes an emitter electrode 3a, a semiconductor layer 3b, a gate electrode 3c, and a collector electrode 3d. Also, the semiconductor element 3 may be, for example, a Schottky-barrier diode (SBD). In this case, the semiconductor element 3 includes a Schottky electrode and an ohmic electrode. The semiconductor element 3 may be a PiN diode.

A material of the semiconductor layer 3b is also not particularly limited. In the present disclosure, the material of the semiconductor layer 3b is preferably constituted by a power semiconductor material. Examples of the power semiconductor material include gallium nitride, silicon carbide, or gallium oxide. According to the semiconductor device 100 of the present disclosure, it is possible to suitably secure heat dissipation in a case where the semiconductor element 3 is constituted by the power semiconductor material and a high-temperature operation is performed.

The semiconductor element 3 of the semiconductor device 100 in FIG. 1 is, for example, an IGBT and includes the first electrode (emitter electrode) 3a and the second electrode (gate electrode) 3c on the first surface of the semiconductor layer 3b. The first electrode 3a and the second electrode 3c are electrically connected to the first wiring layer 1 via the connecting portion 7a and the connecting portion 7b, respectively. The semiconductor device 100 includes the third electrode (collector electrode) 3d on the second surface of the semiconductor layer 3b on the side opposite to the first surface. The third electrode 3d and the second wiring layer 2 are electrically connected to each other via the third connecting portion 7c. In the embodiment of the present disclosure, the connection area between the connecting portion 7a and the emitter electrode 3a occupies 45% or more of the area of an exposed part of the emitter electrode 3a. Also, the connection area between the connecting portion 7b and the gate electrode 3c occupies 45% or more of the area of an exposed part of the gate electrode 3c. In the embodiment of the present disclosure, the connection area between the connecting portion 7a and the emitter electrode 3a preferably occupies 60% or more of the area of the exposed part of the emitter electrode 3a. All of the connection areas and the areas of the exposed parts mean areas in a plan view (the top view in FIG. 1). It is possible to suitably realize such connection areas by forming the connecting portion 7a using a new process for the semiconductor device 100, which will be described later. Note that in a case where a conventional laser via in a build-up substrate is used, it is necessary to secure an annular ring to some extent in view of precision of a laser, and it is thus difficult to employ such large connection areas between the connecting portions and the exposed parts of the electrodes. As a reference example, results obtained by calculating the connection areas between the electrodes and the connecting portions (conductive vias) in a case where an ordinary laser via is used is shown in Table 1.

TABLE 1

| | | | | Area ratio of |
|---|---|---|---|---|
| | | | | laser diameter |
| Laser | Via land | Annular | | with respect to |
| diameter | diameter | ring | Via pitch | each unit area |
| [μm] | [μm] | [μm] | [μm] | [%] |
| 100 | 200 | 50 | 260 | 12.6 |
| 120 | 220 | 50 | 220 | 23.4 |
| 180 | 280 | 50 | 280 | 32.5 |
| 200 | 300 | 50 | 300 | 34.9 |
| 200 | 280 | 40 | 280 | 40.1 |

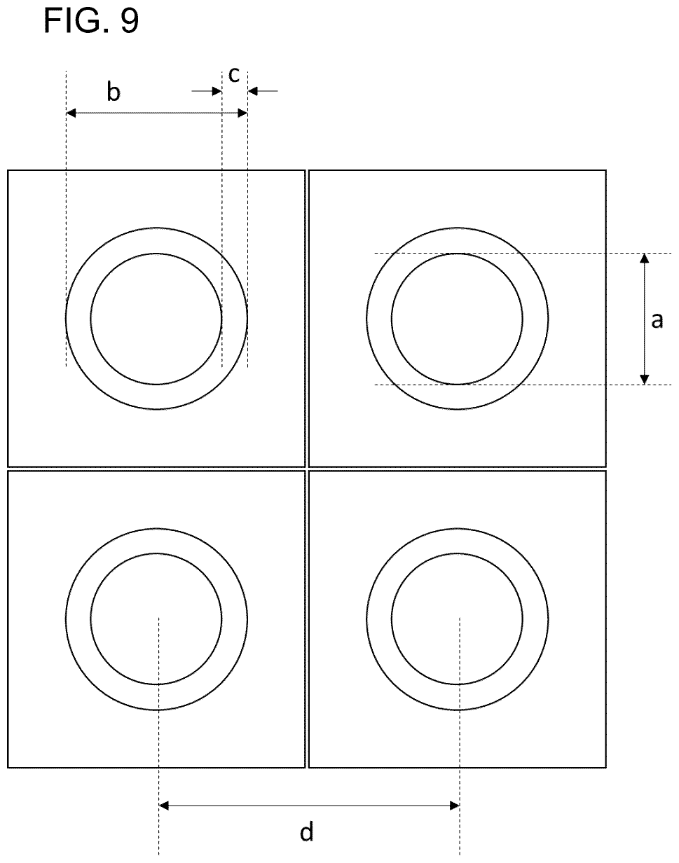

It is possible to ascertain from Table 1 that it is difficult to set an area ratio of a via diameter with respect to the area of the electrode to be 45% or more due to the problem in terms of working precision of the laser via. In a case where a conductive via is formed with a laser without taking a sufficient annular ring, positional deviation may occur, and a failure such as short-circuiting may occur in the semiconductor device. Note that in a case where the laser diameter is set to be greater than 200 μm, light is not collected, and laser energy becomes insufficient, it is thus difficult to perform via working itself on an insulating layer with a typical thickness of equal to or greater than 40 μm and equal to or less than 100 μm, and it is difficult to secure the connection area described above. Note that the laser diameter, the via land diameter, the annular ring, and the via pitch in Table 1 are as illustrated in FIG. 9. In FIG. 9, a represents the laser diameter, b represents the via land diameter, c represents the annular ring, and d represents the via pitch.

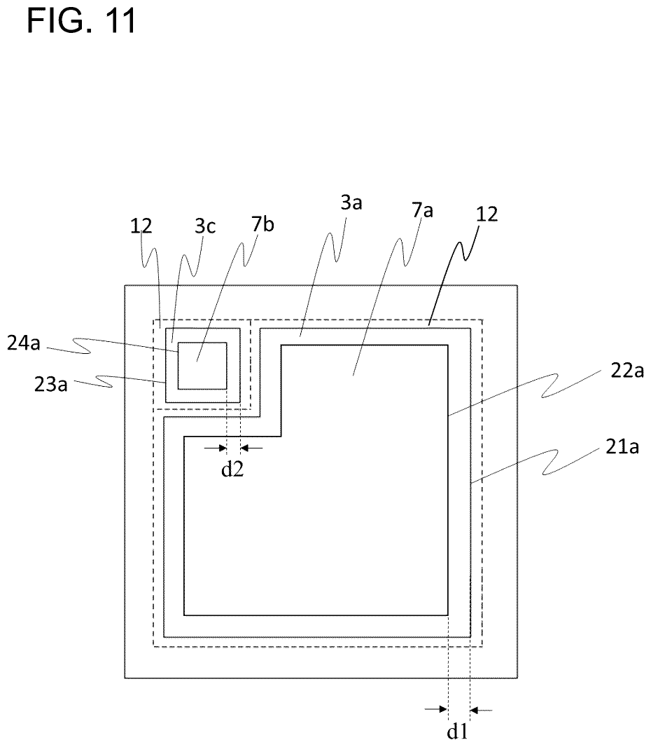

In the embodiment of the present disclosure, an outer periphery of the first electrode 3a includes a first straight portion 21a, an outer periphery of the first connecting portion 7a includes a second straight portion 22a, and the first straight portion 21a and the second straight portion 22a are parallel or substantially parallel to each other as illustrated in FIG. 11 in a plan view. Here, “substantially parallel” includes not only a case where both the first straight portion 21a and the second straight portion 22a are completely parallel to each other but also a case where an inclination of one of the first straight portion 21a and the second straight portion 22a with respect to the other is +10°, for example. In the embodiment of the present disclosure, a distance d1 between the first straight portion 21a and the second straight portion 22a is preferably less than 50 μm and is more preferably less than 30 μm. With such a configuration, a current distribution at the time of power distribution is further uniformized, and it is possible to further satisfactorily suppress a loss due to a resistance component. Furthermore, the first electrode 3a having a polygonal shape is also preferable in order to cause a large current to flow while securing a large area in a case where the second electrode 3c is present in the same plane, in particular, in the embodiment of the present disclosure. In this case, the outer periphery of the first connecting portion 7a preferably has a polygonal shape, and each of sides constituting the polygonal shape of the first connecting portion 7a is preferably provided in parallel or substantially parallel to each corresponding side of the polygonal shape constituted by the outer periphery of the first electrode 3a (hereinafter, also referred to as “similar shapes or substantially similar shapes”) in a plan view. It is possible to obtain a structure suitable for causing a larger current to efficiently flow by providing the connecting portion 7a in this manner.

In the embodiment of the present disclosure, an outer periphery of the second electrode 3c includes a third straight portion 23a, the second connecting portion 7b includes a fourth straight portion 24a, and the third straight portion 23a and the fourth straight portion 24a are parallel or substantially parallel to each other in a plan view as illustrated in FIG. 11. At this time, although the first electrode 3a and the second electrode 3c have different shapes and sizes, the distances between the outer peripheries of the electrodes 3a and 3c and the outer peripheries of the connecting portions 7a and 7b are constant regardless of the shapes and the sizes.

Furthermore, the third electrode 3d includes a fifth straight portion, the third connecting portion 7c includes a sixth straight portion, and the fifth straight portion and the sixth straight portion are parallel or substantially parallel to each other in a plan view in the embodiment of the present disclosure. With such a preferable configuration, it is possible to further reduce an ON resistance of the semiconductor element 3 and to further satisfactorily suppress heat generation due to an operation of the semiconductor element 3. Moreover, since it is possible to obtain a large area of a heat dissipation path through which heat generated by the semiconductor element 3 is caused to escape from the electrodes 3a, 3c, and 3d unlike the related art by including the connecting portions 7a to 7c with similar or substantially similar shapes to the shapes of the electrodes 3a, 3c, and 3d on both surfaces of the semiconductor element 3, it is possible to satisfactorily suppress heat generation due to an operation of the semiconductor element 3. It is possible to suitably implement such a configuration by forming the connecting portions 7a, 7b, and 7c using a new process for the semiconductor device 100, which will be described later. Note that in a case where a conventional laser via in a build-up substrate is used, it is difficult to form the connecting portions such that at least parts of the outer peripheries of the connecting portions follow the straight portions even in a case where the exposed parts of the electrode include straight portions, for example.

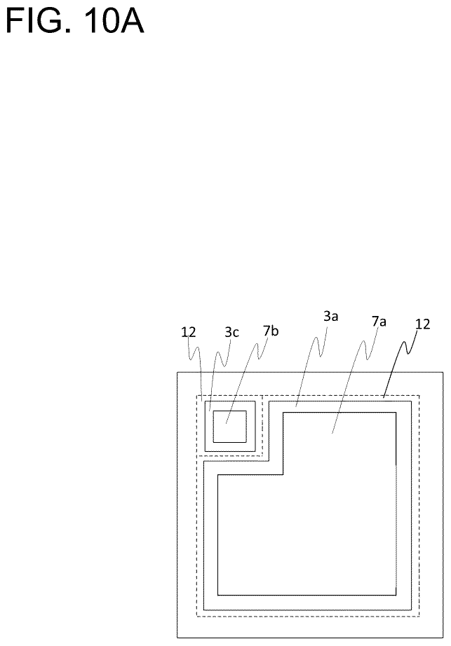

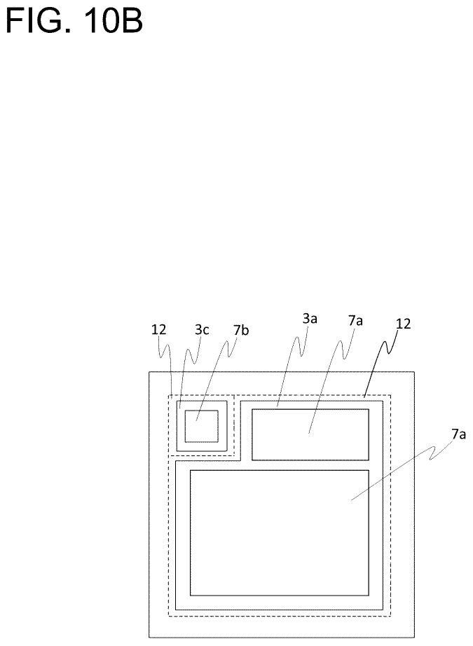

Furthermore, the shortest distance d1 between the first connecting portion 7a and the exposed part of the first electrode 3a is less than 50 μm in a plan view in the embodiment of the present disclosure. The shortest distance d1 is preferably less than 30 μm. Note that although FIG. 11 illustrates, as an example, d1 or d2 as the shortest distance, the present disclosure is not limited to such a case. In the embodiment of the present disclosure, the distance between the outer periphery of the first electrode 3a and the outer periphery of the first connecting portion 7a at the part where the distance between the outer periphery of the first electrode 3a and the outer periphery of the first connecting portion 7a is the shortest in FIG. 11 is defined as the shortest distance between the first connecting portion 7a and the end portion of the exposed part of the first electrode 3a. Note that in the embodiment of the present disclosure, the shortest distance between the first connecting portion 7a and the end portion of the exposed part of the first electrode 3a is preferably less than 50 μm in a plan view. With such a configuration, it is possible to further uniformize a current distribution at the time of power distribution. Also, a shortest distance d2 between the second connecting portion 7b and the exposed part of the second electrode 3c is less than 50 μm in a plan view. Furthermore, the shortest distance between the third connecting portion 7c and the exposed part of the third electrode 3d is less than 50 μm in a plan view. With such a preferable configuration, it is possible to further reduce an ON resistance of the semiconductor element 3 and to further satisfactorily suppress heat generation due to an operation of the semiconductor element 3. Furthermore, it is possible to obtain a large area of the heat dissipation path through which heat generated by the semiconductor element 3 is caused to escape from the electrodes 3a, 3c, and 3d unlike the related art by including the connecting portions 7a to 7c with shapes that are close to those of the electrodes 3a, 3c, and 3d on both surfaces of the semiconductor element 3, and to thereby satisfactorily suppress heat generation due to an operation of the semiconductor element 3. Such a configuration is able to be suitably realized by forming the connecting portions 7a, 7b, and 7c using the new process for the semiconductor device 100, which will be described later. Note that in a case where a conventional laser via in a build-up substrate is used, it is necessary to perform working while securing an annular ring of 50 μm for typical positional accuracy of the laser via and mounting precision of the semiconductor element, for example, and it is thus difficult to form the connecting portions with the configuration as described above. Also, although one side of the first electrode 3a is several mm long, one side of the second electrode 3c is several hundreds of μm, and the areas of the electrodes significantly differ from each other (for example, the difference is double or more) in the aspect illustrated in FIG. 10, it is possible to cause the connecting portions (first connecting portion 7a and second connecting portion 7b) to be located closer to the end portions of the exposed parts of the electrodes 3a and 3c while maintaining reliability of electrical connection according to the embodiment of the present disclosure. It is difficult to achieve this by the method using the conventional laser via and a method of forming bumps on the electrodes by plating using a plating resist and establishing connection as connecting portions.

In the semiconductor device 100 in FIG. 1, the first wiring layer 1 and the second wiring layer 2 are electrically connected to each other via a metal block 10. Note that the metal block 10 has a height that is equal to or greater than the thickness of the semiconductor element 3 as illustrated in FIG. 1. Also, the first wiring layer 1 and/or the second wiring layer 2 and the metal block 10 are preferably electrically connected through direct connection. According to the suitable manufacturing method, which will be described later, it is possible to obtain a structure in which the first wiring layer 1 and/or the second wiring layer 2 are/is connected to the metal block 10 such that the first wiring layer 1 and/or the second wiring layer 2 cover(s) the metal block 10. With such a structure, it is possible to further enhance electrical connectivity and heat dissipation between the first wiring layer 1 and the second wiring layer 2 (holding layer 2A). Note that a material constituting the metal block 10 is also not particularly limited as long as it does not depart from the scope of the present disclosure. Examples of the material constituting the metal block 10 include Cu, Au, Al, Ag, Fe, Ti, Ni, Pt, Pd, and alloys thereof (which may contain other metal).

Also, the semiconductor element 3 includes an insulating film (passivation film) 12 that covers at least an outer end portion of the first electrode 3a and/or the second electrode 3c and includes an opening portion. In the semiconductor device 100 in FIG. 1, a part of the first electrode 3a and/or the second electrode 3c exposed from the insulating film 12 at the opening portion in the insulating film 12 constitutes the exposed part of the first electrode 3a and/or the second electrode 3c. Note that the thickness of the insulating film 12 is not particularly limited as long as it does not depart from the scope of the present disclosure. In the embodiment of the present disclosure, the thickness of the insulating film 12 on the first electrode 3a and/or the second electrode 3c is equal to or less than 10 μm, for example, and is more preferably equal to or less than 5 μm. A lower limit of the thickness of the insulating film 12 on the first electrode 3a and/or the second electrode 3c is also not particularly limited, and typically, it is only necessary for the insulating film 12 to have a thickness with which the insulating film 12 is able to cover the thickness of the electrode 3a and/or the electrode 3c. A lower limit of a difference between the thicknesses of the insulating film 12 and the first electrode 3a and/or the second electrode 3c is also not particularly limited, and typically, it is only necessary for the insulating film to have a thickness with which the thicknesses of the electrodes are able to be covered. Moreover, a material of the insulating film (passivation film) 12 is also not particularly limited. Examples of the material of the insulating film (passivation film) 12 include an SiO₂ film, a silicon nitride film, a polysilicon film, a phosphorus-added SiO₂ film (PSG film), a boron-added SiO₂ film, a phosphorus-boron-added SiO₂ film (BPSG film), and a polyimide film. Examples of a method of forming the insulating film 12 include a CVD method, an atmospheric-pressure CVD method, a plasma CVD method, and a mist CVD method. According to the embodiment of the present disclosure, the thicknesses of the first connecting portion 7a and the second connecting portion 7b correspond to the difference between the thickness of the insulating film 12 and the thickness of the insulating film 12 on the first electrode 3a and/or the second electrode 3c, and it is thus possible to cause the first connecting portion 7a and the second connecting portion 7b to have minimum necessary thicknesses and to obtain a structure that is more advantageous for heat dissipation.

A constituent material of the first wiring layer 1 and the second wiring layer 2 is not particularly limited as long as the material has conductivity. Examples of the constituent material of the first wiring layer 1 and/or the second wiring layer 2 include Cu, Au, Al, Ag, Fe, Ti, Ni, Pt, Pd, and alloys thereof (which may contain other metal). In the present disclosure, the constituent material of the first wiring layer 1 and/or the second wiring layer is preferably Cu. Also, a constituent material of the connecting portions 7a, 7b, and 7c is not particularly limited as long as the material has conductivity. Examples of the constituent material of the connecting portions 7a, 7b, and 7c include Cu, Au, Al, Ag, Fe, Ti, Ni, Pt, Pd, alloys thereof (which may contain other metal), and a conductive resin paste. Also, these materials (connecting portions 7a, 7b, and 7c) may form multilayer structures to increase adhesion strength. In the present disclosure, the constituent material of the connecting portions 7a, 7b, and 7c is preferably Cu or a Cu alloy.

In the embodiment of the present disclosure, the first wiring layer 1 is preferably the outermost wiring layer as illustrated in FIG. 1 in terms of heat dissipation. It is also preferable that the semiconductor element 3 include an insulating film (for example, a passivation film) 12 that covers at least the outer end portion of the first electrode 3a and includes an opening portion. Moreover, the first wiring layer 1 is preferably in contact with the insulator 5 since it is possible to increase the heat dissipation area through expansion to a larger area than the area of the semiconductor element 3. In this case, the interface between the first wiring layer 1 and the insulating film 12 is preferably located on the side further upward (upward on paper of FIG. 1) in the stacking direction than the interface between the first wiring layer 1 and the insulator 5. Note that in a case where another layer such as an adhesive layer is present between the first wiring layer 1 and the insulator 5, the interface between the first wiring layer 1 and the insulator 5 is read as an interface between the first wiring layer 1 and another layer instead. Also, the first wiring layer 1 and the first connecting portion 7a and/or the second connecting portion 7b are preferably integrally formed. In a case where the first wiring layer 1 and the first connecting portion 7a and/or the second connecting portion 7b are integrally formed using the same metal or the like, a part from the surface connected to the first electrode 3a to the surface where the area in a plan view changes in the stacking direction of the semiconductor element 3 (the same plane as the upper surface of the insulating film 12) is defined as the first connecting portion 7a and/or the second connecting portion 7b as illustrated in FIG. 1. The aforementioned one preferable configuration or plurality of preferable configurations bring(s) about more satisfactory heat dissipation of heat generated by the semiconductor element 3 and/or more satisfactory electrical connectivity between the semiconductor element 3 and the first wiring layer 1 alone or in combination with the connection area described above. According to the preferable manufacturing method, which will be described later, the interface between the first connecting portion 7a and the first electrode 3a and the interface between the first wiring layer 1 and the insulator 5 are located in the same plane or substantially the same plane. Moreover, it is also preferable that the upper surface of the insulator 5 and the upper surface of the first electrode 3a and/or the second electrode 3c be located in the same plane or substantially the same plane. With such a configuration, it is possible to reduce the thicknesses of the connecting portions and obtain a more advantageous structure for heat dissipation. Note that “substantially the same plane” means that a difference in heights of both the elements is about a manufacturing error (within ±10%). Also, the upper surface means the surface on the upper side on paper of FIG. 1.

The first connecting portion 7a may be configured of a single connecting body or may be configured of a plurality of connecting bodies as long as the aforementioned condition of the connection area with the first electrode 3a, a relationship with the first electrode 3a, or the like is satisfied. Note that the case where the first connecting portion 7a is configured of a plurality of connecting bodies means that the first connecting portion 7a is split into two or more parts in a plane cut along a plane that is parallel to the surface of the electrode 3a between the surface of the first electrode 3a and the surface of the insulating film 12 (the interface between the first connecting portion 7a and the first wiring layer 1), for example. The top views of FIGS. 10A and 10B are diagrams for explaining the number and the shape of (the connecting bodies of) the first connecting portion 7a and a relationship between the insulating film 12 and the first electrode 3a. The outer peripheral parts (the parts surrounded by the solid lines) of 3a and 3c in FIGS. 10A and 10B indicate exposed parts of the first electrode 3a and the second electrode 3c exposed from the insulating film 12 at the opening portions in the insulating film 12. Also, the dotted lines in FIGS. 10A and 10B each indicate the outer periphery of the insulating film 12. FIG. 10A illustrates a top view in a case where the first connecting portion 7a is configured of a single connecting body, and FIG. 10B illustrates a top view in a case where the first connecting portion 7a is configured of a plurality of connecting bodies. Note that both FIGS. 10A and 10B are plan views cut along a plane that is parallel to the surface of the first electrode (second electrode) between the surface of the first electrode 3a (second electrode 3c) and the interface between the insulating film 12 and the first wiring layer 1. In the embodiment of the present disclosure, the first connecting portion 7a and/or the second connecting portion 7b may be configured of a single connecting body as illustrated in FIG. 10A. In the embodiment of the present disclosure, it is also preferable that the first connecting portion 7a and/or the second connecting portion 7b include a plurality of connecting bodies with mutually different areas in a plan view as illustrated in FIG. 10B. It is possible to suppress breakage due to a thermal stress resulting from a difference between thermal expansion coefficients of the material constituting the connecting portions and the semiconductor element 3 in a case where the electrode portions are large and wide by splitting the connecting portion.

In the embodiment of the present disclosure, the holding layer 2A includes a projecting portion that is located immediately below the semiconductor element 3 and is at least partially buried in the insulator 5. Specifically, the projecting portion is a part of the holding layer 2A located on the side further upward than the interface between the insulator 5 and the second wiring layer 2, that is, the third connecting portion 7c. Note that it is only necessary for the projecting portion to be buried in the insulator 5 immediately below the semiconductor element 3 and the projecting portion may not be the connecting portion 7c. In other words, the projecting portion may not have a function of electrically connecting the third electrode 3d and the second wiring layer 2. Moreover, the holding layer 2A may not include the projecting portion.

A material constituting the insulator 5 is not particularly limited as long as it does not depart from the scope of the present disclosure. Examples of the constituent material of the insulator 5 include an epoxy resin, a cyanate ester resin, an acrylic resin, a polyimide resin, and a silicon resin. Also, the thickness of the insulator 5 is similar or substantially similar to the thickness of the semiconductor element 3 (the thickness from the lower surface (the lower surface of the third electrode 3c) to the upper surface (the upper surface of the insulating film 12) of the semiconductor element). More specifically, the thickness of the insulator 5 is equal to or greater than 1.0 times and equal to or less than 1.2 times the thickness of the semiconductor element 3. In the embodiment of the present disclosure, the surface of the first electrode 3a, the surface of the second electrode 3c, and one-side surface of the insulator 5 are in substantially the same plane in this manner, and the thicknesses of the connecting portions 7a and 7b are thus considerably thin (equal to or less than 10 μm, or preferably equal to or less than 5 μm, for example). Furthermore, since it is possible to reduce the thickness of the insulator 5 as described above, a more advantageous structure for electrical connection and thermal connection between the first wiring layer 1 and the second wiring layer 2 is obtained.

Insulating protective layers 9b and 9a that form casing walls of a module may be provided on the upper surface of the first wiring layer 1 and the lower surface of the second wiring layer 2, respectively. The insulating protective layer 9a is produced using a material with an electrical insulating property such as a solder resist, for example, and the insulating protective layer 9b is produced using a material that allows heat dissipation while establishing insulation from outside of the module such as a thermal interface material (TIM), for example. Although not illustrated in the drawings here, a heat sink such as a heat dissipation fin, for example, is connected to the lower surface of the insulating protective layer 9a, and heat generated from the semiconductor element 3 that is a heat source is effectively dissipated to the outside of the module. Also, a control system (including a gate driver and the like) of the semiconductor element 3, a high-order system, or a control target, for example, is disposed on the upper surfaces of the first wiring layer 1 and the insulating protective layer 9b, and signals and power are exchanged therebetween.

Operations and the like of the semiconductor device 100 according to the embodiment of the present disclosure configured as described above will be described in detail.

First, once a gate driver, which is not illustrated, outputs a control signal (switching signal), the semiconductor element 3 operates, and switching control is performed. In this manner, a desired pulse waveform is generated by the semiconductor element 3, and the pulse waveform is output as a drive signal from the first electrode 3a. The drive signal is given to a control target, which is not illustrated. In a case where the semiconductor element 3 is an IGBT, for example, switching control of the IGBT is performed by supplying a control signal from the gate driver, which is not illustrated, to a gate electrode 3c of the IGBT.

In addition, an electric signal and a processing signal are collected via an electric circuit formed in the first wiring layer 1 and are sent to a control system via the electric circuit in the second wiring layer 2 when the semiconductor element 3 operates. In other words, the electric signal and the processing signal sent to the control system are exchanged via the second wiring layer 2. Therefore, electric signals input to or output from the first electrode 3a and the second electrode 3c of the semiconductor element 3 are also given to the electric circuit in the first wiring layer 1 via the first connecting portion 7a and the second connecting portion 7b, and further conduct through a loop connected to the second wiring layer 2 via the metal block 10. In this manner, the first wiring layer 1 and the second wiring layer 2 contribute to electrical conduction of the semiconductor element 3 that connects the first and second wiring layers 1 and 2 via the metal block 10.

Also, heat inside the module, that is, heat generated from the semiconductor element 3 is dissipated toward the upper side or the lower side of the semiconductor element 3 via the first to third connecting portions 7a to 7c and the metal block 10. The embodiment of the present disclosure is configured such that heat dissipation from above the semiconductor device 100 is effectively performed by a heat dissipation mechanism such as a heat dissipation fin, which is not illustrated, being attached to the first wiring layer 1 on the upper side as described above.

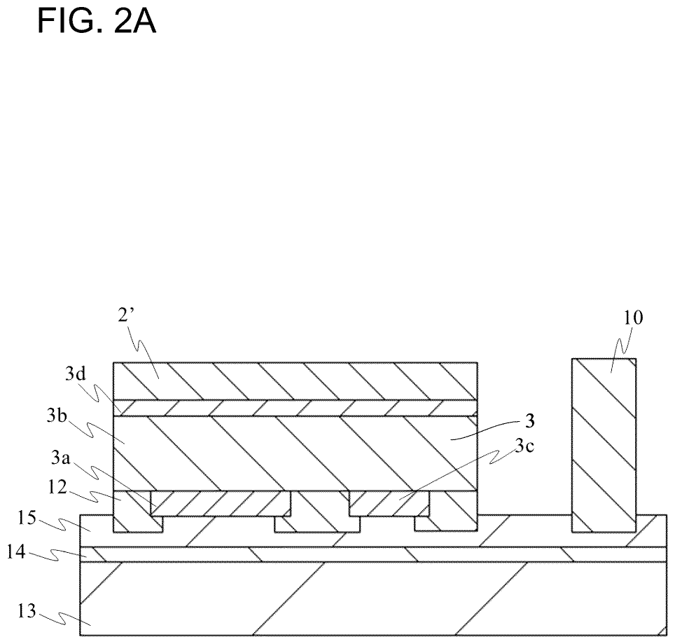

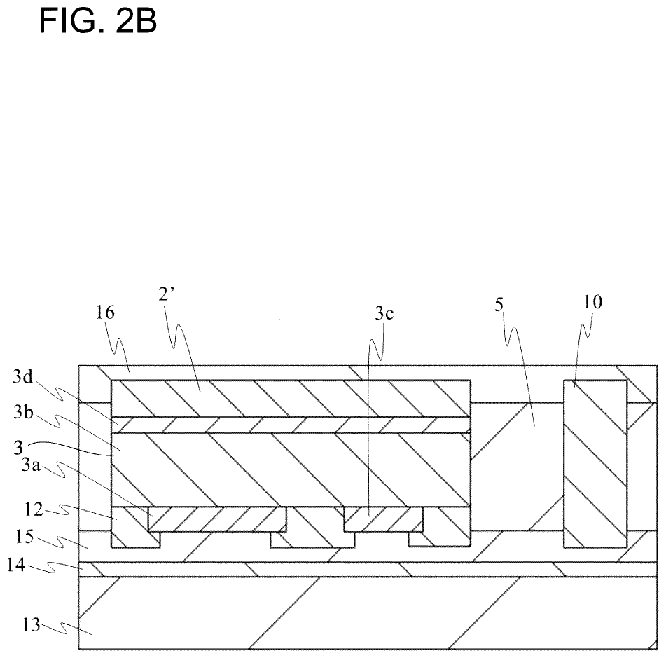

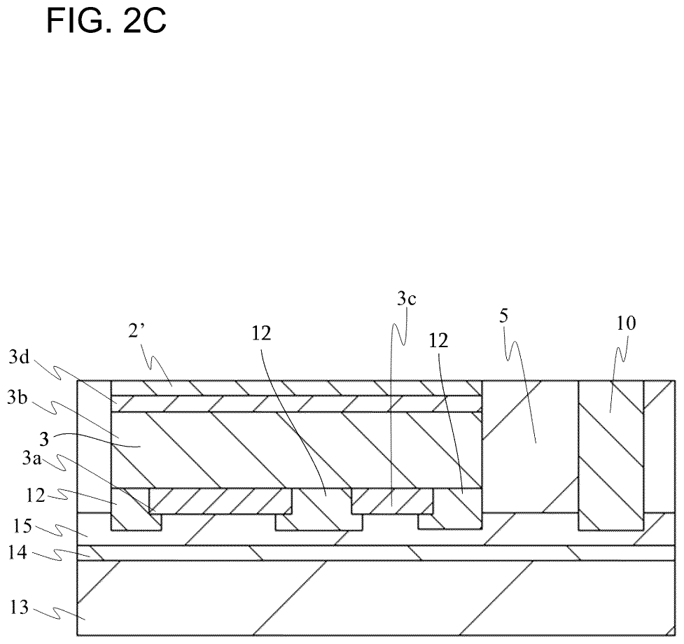

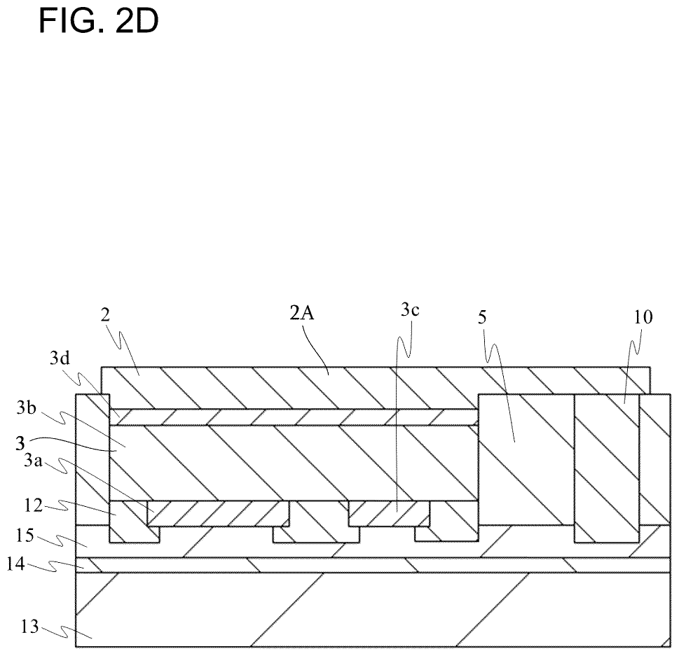

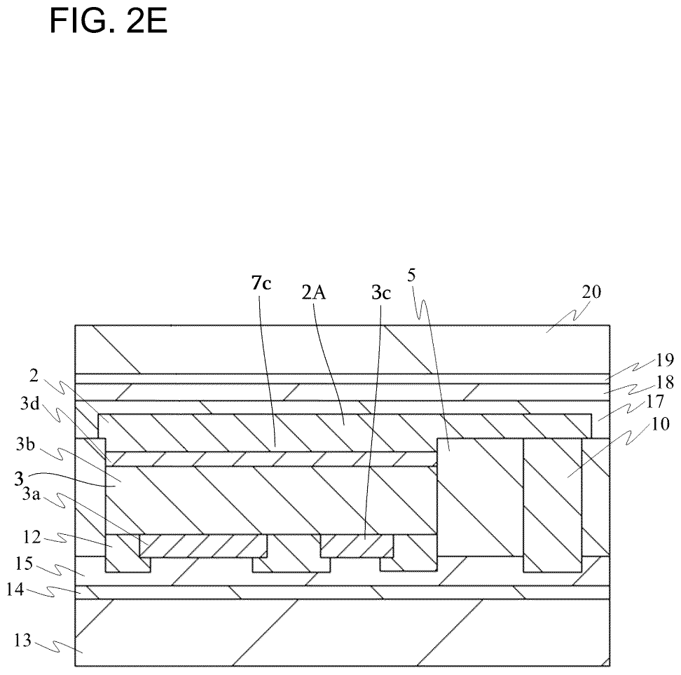

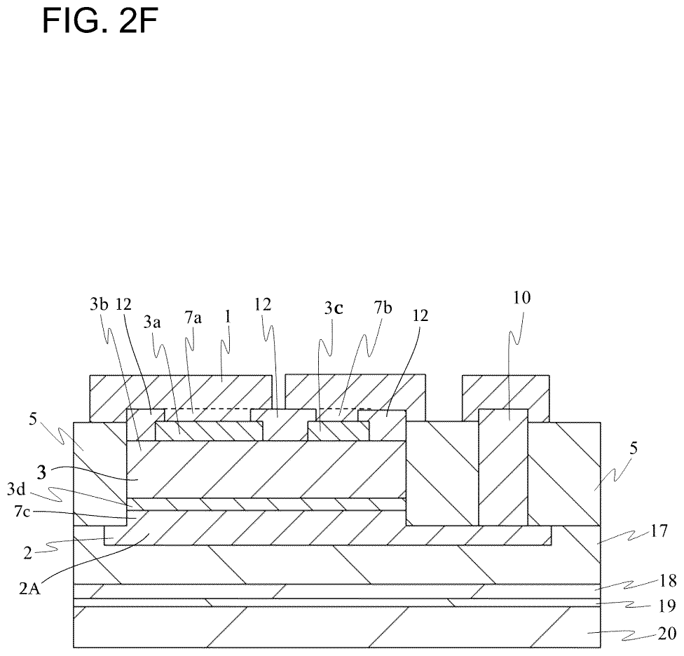

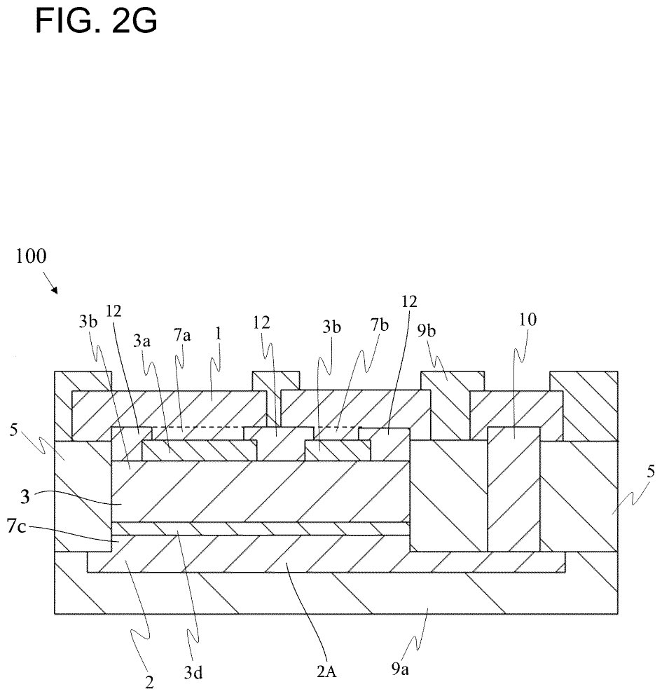

Next, a specific manufacturing process of the semiconductor device 100 according to one embodiment of the present disclosure will be described in more detail using the schematic sectional views illustrated in FIGS. 2A to 2G. Note that parts of such a method of manufacturing the semiconductor device 100 or combinations thereof are also new and useful and are included in the present disclosure. According to a method of manufacturing the semiconductor device 100 in one embodiment of the present disclosure, the semiconductor device 100 is suitably manufactured by using a manufacturing method including: forming, in the semiconductor element 3 that includes the semiconductor layer 3b and the first electrode 3a disposed on the first surface of the semiconductor layer 3b with at least a part of the first electrode 3a exposed, a protective portion that covers the exposed part of the first electrode 3a; sealing the semiconductor element 3 with a resin; removing the protective portion and exposing the at least exposed part of the first electrode 3a; and forming the connecting portions 7a and 7b and the wiring layer 1 on the exposed part, for example. According to such a manufacturing method, it is possible to minimize the heights of the connecting portions 7a and 7b and to easily obtain the semiconductor device 100 that is excellent in heat dissipation and the like. In the embodiment of the present disclosure, the semiconductor element 3 preferably includes the insulating film 12 that covers at least an outer end portion of the first electrode 3a and includes an opening portion, and the exposed part of the first electrode 3a is preferably a part exposed from the insulating film 12 at the opening portion. Also, the connecting portions 7a and 7b and the wiring layer 1 are preferably integrally formed in the embodiment of the present disclosure. In addition, the semiconductor element 3 may be adapted such that the third electrode 3d is disposed in a manner on the second surface of the semiconductor layer 3b in the embodiment of the present disclosure.

Also, it is possible to obtain the semiconductor device 100 suitably by using the following manufacturing method in a case where the semiconductor element 3 is a semiconductor element 3 in which the first electrode 3a and the second electrode 3c are disposed on the first surface of the semiconductor layer 3b and further, the insulating film (passivation film) 12 that covers at least the outer end portions of the first electrode 3a and the second electrode 3c and includes an opening portion is formed therein in the embodiment of the present disclosure. A method of manufacturing the semiconductor device 100 according to one embodiment of the present disclosure includes at least: forming, in the semiconductor element 3 that includes the first electrode 3a and the second electrode 3c disposed on the first surface of the semiconductor layer 3b and the insulating film 12 that covers at least the outer end portions of the first electrode 3a and the second electrode 3c and includes the opening portion, the protective portion that covers the first and second electrodes 3a and 3c and the insulating film 12; sealing the semiconductor element 3 with a resin; removing the protective portion and exposing the first electrode 3a, the second electrode 3c, and the insulating film 12 in a state where the insulating film 12 covers at least the outer end portions of the first electrode 3a and the second electrode 3c; and forming the connecting portions 7a and 7b and the wiring layer 1 at the exposed parts of the first electrode 3a and the second electrode 3c exposed from the insulating film 12 at the opening portion.

Furthermore, in the case where the semiconductor element 3 is adapted such that the first electrode 3a and the second electrode 3c are disposed on the first surface of the semiconductor layer 3b and the third electrode 3d is disposed on the side of the second surface of the semiconductor layer 3b which is the side opposite to the first surface, it is possible to manufacture the semiconductor device 100 suitably by using the following manufacturing method in the embodiment of the present disclosure. According to the method of manufacturing the semiconductor device 100 according to one embodiment of the present disclosure, it is possible to suitably manufacture the semiconductor device 100 by a manufacturing method including: forming, in the semiconductor element 3 that includes the first electrode 3a and the second electrode 3c disposed on the first surface of the semiconductor layer 3b and the third electrode 3d disposed on the second surface on the side opposite to the first surface with at least parts of the first electrode 3a and the second electrode 3c exposed, the protective portion that covers the exposed parts of the first and second electrodes 3a and 3c; sealing the semiconductor element 3 with a resin; exposing at least a part of the third electrode 3d; forming the second wiring layer 2 at the exposed part of the third electrode 3d; removing the protective portion and exposing at least parts of the first electrode 3a and the second electrode 3c; and forming the connecting portions 7a and 7b and the first wiring layer 1 at the exposed parts of the first electrode 3a and the second electrode 3c. In the aforementioned manufacturing method, at least a part of the third electrode 3d is preferably exposed by polishing. In this case, it is possible to more easily enhance controllability of height precision of the semiconductor element 3 while suppressing influences on the first electrode 3a and the second electrode 3c by performing the polishing after the protection of the exposed parts of the first electrode 3a and the second electrode 3c and the sealing of the semiconductor element 3 with the resin.

FIG. 2A illustrates a structural body in which a support substrate 13 is formed on the side of the first surface of the semiconductor element 3 via a temporary fixing adhesive layer 15 and a peeling layer 14. As the support substrate 13, a glass substrate is used, for example. Note that the metal block 10 is also bonded to the support substrate 13 with the temporary fixing adhesive layer 15. The semiconductor element 3 is, for example, an IGBT and includes the semiconductor layer 3b, the first electrode (emitter electrode) 3a and the second electrode (gate electrode) 3c disposed on the first surface of the semiconductor layer 3b, and the third electrode (collector electrode) 3d disposed on the side opposite to the first surface of the semiconductor layer 3b. In FIG. 2A, the semiconductor element 3 on the side of the first surface is temporarily fixed to the support substrate 13. Also, a metal layer 2′ may be formed on the third electrode (collector electrode) 3d in the embodiment of the present disclosure. It is possible to reduce influences on the third electrode 3d without strictly managing precision in a polishing process, which will be described later, and further, it is possible to further improve precision of variations in thicknesses among lots of the semiconductor elements 3 and precision of variations in heights of the semiconductor elements 3 and the metal blocks 10, by forming the metal layer 2′ in this manner.

A mold shaping method using a mold release film 16 is used on the structural body illustrated in FIG. 2A, a sealing material as the insulator 5 is injected, and a structural body illustrated in FIG. 2B is obtained. In the structural body in FIG. 2B, parts of the semiconductor element 3 and the metal block 10 are embedded in the insulator 5. Note that a silicone resin or an epoxy resin, for example, is used as the sealing material. As a molding method of injecting the sealing material, a known method is used. In the embodiment of the present disclosure, a transfer mold method or a compression mold method, for example, is preferably used. Also, since the semiconductor layer 3b on the side of the first surface is protected by the temporary fixing adhesive layer 15 in the embodiment of the present disclosure, a state where the semiconductor layer 3b on the side of the first layer is not embedded by the insulator 5 even through the molding is maintained.

After the structural body illustrated in FIG. 2B is obtained, the semiconductor element 3 on the side of the second surface is polished and flattened using a known polishing method, thereby obtaining a structural body illustrated in FIG. 2C. Examples of the polishing method include a chemical mechanical polishing (CMP) method. Thereafter, metal for the second wiring layer 2 is formed using a known method such as a plating method (an electrolytic plating method or an electroless plating method), patterning is performed using a known patterning method, thereby obtaining a structural body illustrated in FIG. 2D. Next, as a preparation for proceeding with working on the semiconductor layer 3b on the side of the first surface, a resist 17, the temporary fixing adhesive layer 18, the peeling layer 19, and a support substrate 20 are bonded in this order also on the side of the second surface of the semiconductor layer 3b which is the side opposite to the first surface, thereby obtaining a structural body illustrated in FIG. 2E.

Then, the structural body illustrated in FIG. 2E is subjected to UV irradiation, for example, the support substrate 13 is peeled off from the peeling layer 14, and further, the temporary fixing adhesive layer 15 is removed through washing to expose the first electrode 3a and the second electrode 3c. At this time, the insulating film 12 is maintained in a state where the insulating film 12 covers at least the outer end portions of the first electrode 3a and the second electrode 3c (a state where it is possible to establish insulation between the first electrode 3a and the second electrode 3c). Furthermore, a metal layer to be used as the first wiring layer 1 is formed on the entire surface using a known method such as a plating method (an electrolytic plating method or an electroless plating method), and patterning for wiring is performed using a known patterning method, thereby obtaining a structural body illustrated in FIG. 2F. For the electrodes 3a and 3c of the semiconductor element 3 embedded in the insulator 5 in this manner, the electrodes 3a and 3c are exposed without working any hole in the insulator 5, and the electrodes 3a and 3c and the first wiring layer 1 are electrically connected. Therefore, it is possible to establish connection to the exposed surfaces of the electrodes 3a and 3c in substantially the same areas. Furthermore, the lengths of the connecting portions 7a and 7b between the first wiring layer 1 and the first and second electrodes 3a and 3c are as considerably short as several μm to 10 μm, which is about the thickness of the insulating layer on the semiconductor element 3. Thereafter, the support substrate 20, the peeling layer 19, the temporary fixing adhesive layer 18, and the resist 17 are removed by a process that is similar to that described above. Then, the insulating protective layers 9a and 9b such as solder resists are formed using a known method, thereby obtaining a semiconductor device 100 illustrated in FIG. 2G.

It is possible to dissipate heat generated from the semiconductor element 3 that is a heat source to the outside of the module by connecting a heat sink such as a heat dissipation fin to the lower surface of the insulating protective layer 9a, for example, after the structural body in FIG. 2G is obtained. Also, it is possible to exchange signals and power with each other by disposing a control system and a high order system of the semiconductor element 3 or a control target, for example, above the first wiring layer 1 and the insulating protective layer 9b.

Although the case where the semiconductor device 100 according to the embodiment of the present disclosure incorporates the one semiconductor element 3 has been described as an example, the number of semiconductor elements 3 is not limited, and a plurality of semiconductor elements may be incorporated. In both cases, it is possible to expect the aforementioned effects of the present disclosure.

Also, although the semiconductor element 3 illustrated in FIG. 1 is a vertical element, the semiconductor element 3 may be a horizontal element provided with electrodes only on one surface. In this case, the surface on which the electrodes are provided may be located on the upper side or the lower side in the direction on paper of the drawing, and it is possible to expect the aforementioned effects of the present disclosure.

In a case where a power semiconductor element is mounted as the semiconductor element 3, a case where a silicon carbide (SiC), gallium nitride (GaN), gallium oxide (Ga₂O₃), or the like is used as a semiconductor material of the power semiconductor is particularly useful. In particular, it is considerably useful in a case where a semiconductor element 3 using gallium oxide (α-Ga₂O₃) with a corundum structure with a high band gap or gallium oxide (β-Ga₂O₃) with a β-gallia structure. Since these semiconductor materials have particularly large heat generation at the time of an operation, an application thereof to the present disclosure that is also excellent in size reduction of the module and a heat dissipation property contributes not only to an increase in density of the semiconductor device 100 but also to an improvement in reliability.

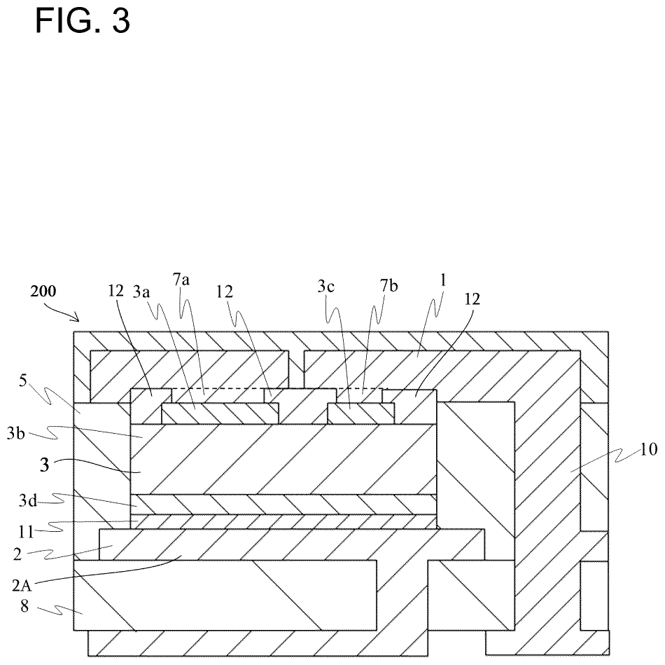

FIG. 3 is a sectional view schematically illustrating a semiconductor device 200 according to another embodiment of the present disclosure. Note that illustration or description of configurations similar to those in the semiconductor device 100 illustrated in FIG. 1 may be omitted. The semiconductor device 200 illustrated in FIG. 3 includes a semiconductor element 3 that is disposed between a first wiring layer 1 and a holding layer 2A and an insulator 5 in which at least a part of the semiconductor element 3 is embedded. In the semiconductor device 200 in FIG. 3, the first wiring layer 1 constitutes an upper wiring layer, and the holding layer 2A constitutes a second wiring layer (lower wiring layer). An electrode 3a of the semiconductor element 3 is electrically connected to the first wiring layer 1 via a first connecting portion 7a. An electrode 3c of the semiconductor element 3 is electrically connected to the first wiring layer 1 via a second connecting portion 7b. An electrode 3d of the semiconductor element is electrically connected to the second wiring layer 2 via a conductive adhesive layer 11. The conductive adhesive layer 11 is a projecting portion buried in the insulator 5. Also, the first wiring layer 1 and the second wiring layer 2 are electrically connected via a through-hole 10. Note that the second wiring layer 2 is constituted by copper foils formed on both surfaces of a base material 8, and the copper foil on the side of the upper portion and the copper foil on the side of the lower portion are connected to each other via a through-hole. In the semiconductor device 200 in FIG. 3, a connection area between the first connecting portion 7a and the first electrode 3a occupies 45% or more of the area of an exposed part of the first electrode 3a. Also, a connection area between the second connecting portion 7b and the second electrode 3c occupies 45% or more of the area of an exposed part of the second electrode 3c. Moreover, in the semiconductor device 200 in FIG. 3, the outer periphery of the first electrode 3a includes a first straight portion, the outer periphery of the first connecting portion 7a includes a second straight portion, and the first straight portion and the second straight portion are parallel or substantially parallel to each other in a plan view. Here, “substantially parallel” includes not only a case where both the first straight portion and the second straight portion are completely parallel to each other but also a case where an inclination of one of the first straight portion and the second straight portion with respect to the other is +10°, for example. In the embodiment of the present disclosure, the distance between the first straight portion and the second straight portion is preferably less than 50 μm, and is more preferably less than 30 μm. Also, in the embodiment of the present disclosure, the outer periphery of the second electrode 3c includes a third straight portion, the second connecting portion 7b includes a fourth straight portion, and the third straight portion and the fourth straight portion are parallel or substantially parallel to each other in a plan view. In the present disclosure, it is possible to achieve similar effects even in a case where a print substrate such as a so-called PCB substrate is used as in the semiconductor device 200 illustrated in FIG. 3.

Examples of a material of the adhesive layer (conductive adhesive layer) 11 include a silver (Ag) sintered material, a copper sintered material, a solder, a silver paste, and an AuGe-based alloy. Note that the first semiconductor element 3 and the second wiring layer 2 may also be connected through direct bonding (for example, diffusion bonding), and in such a case, the adhesive layer 11 is not needed. Therefore, it is also possible to configure the embodiment of the present disclosure with the adhesive layer 11 omitted.

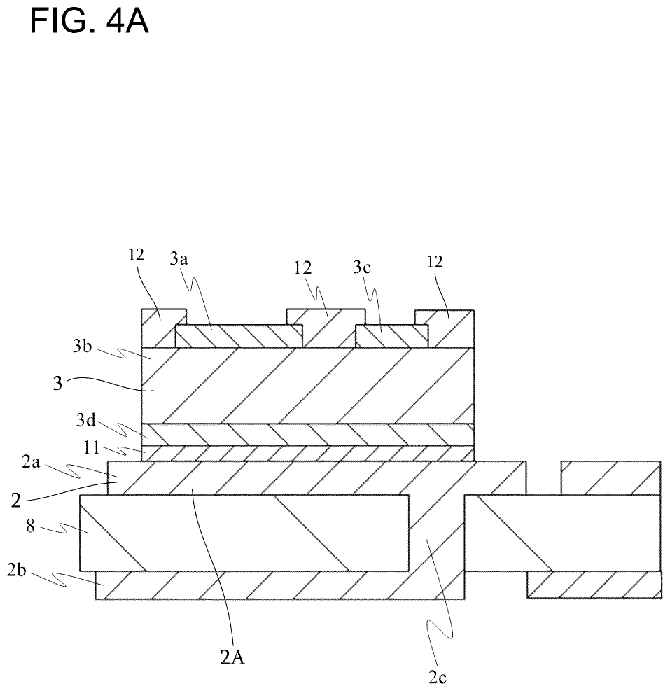

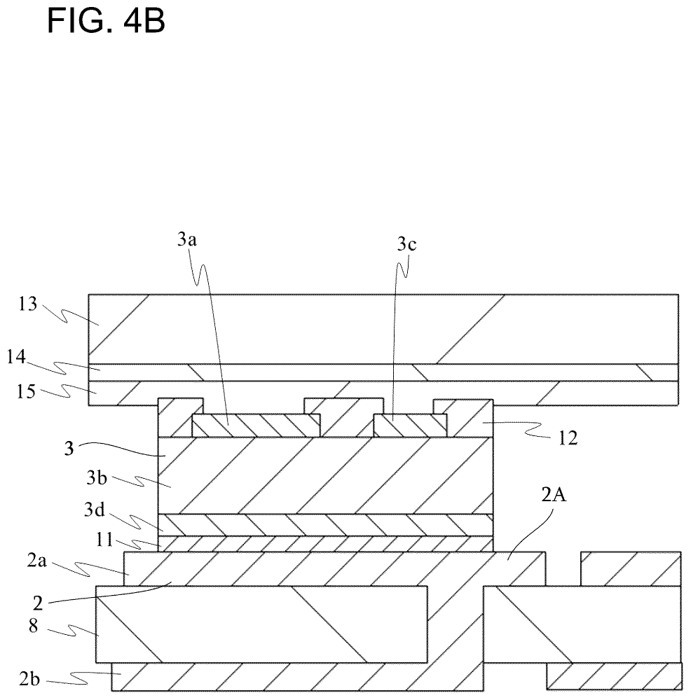

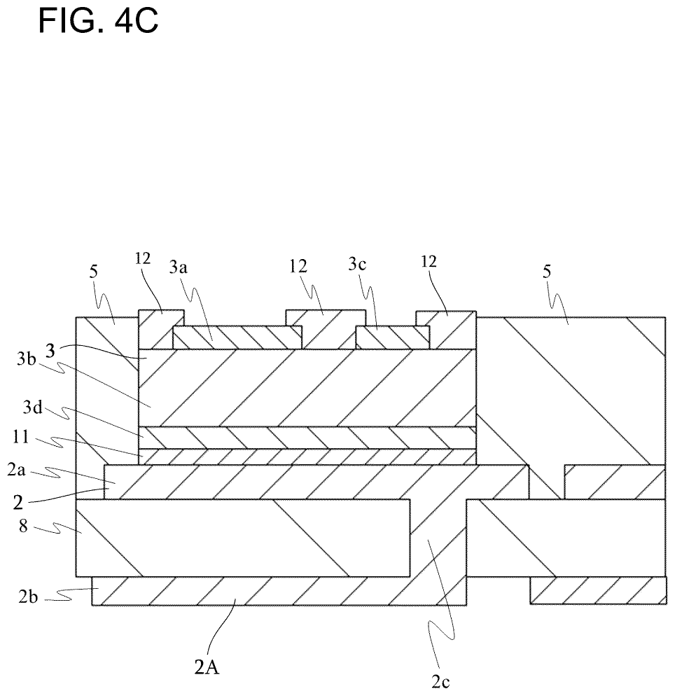

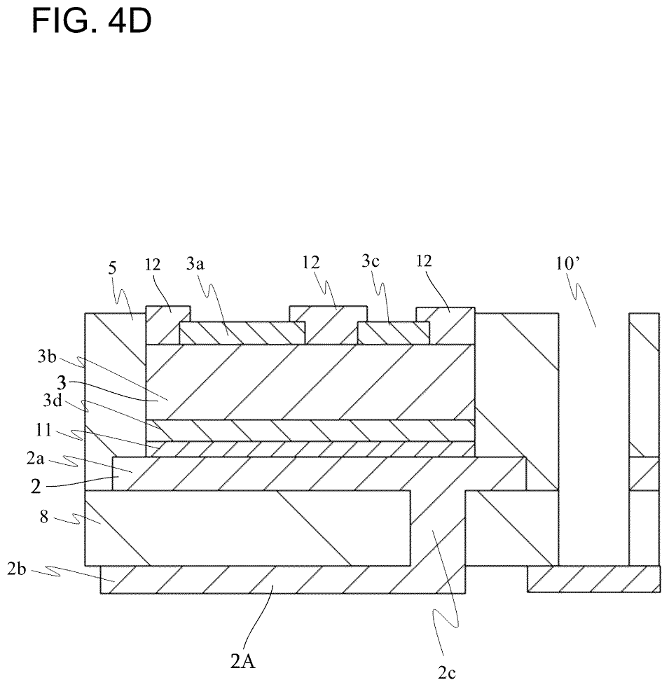

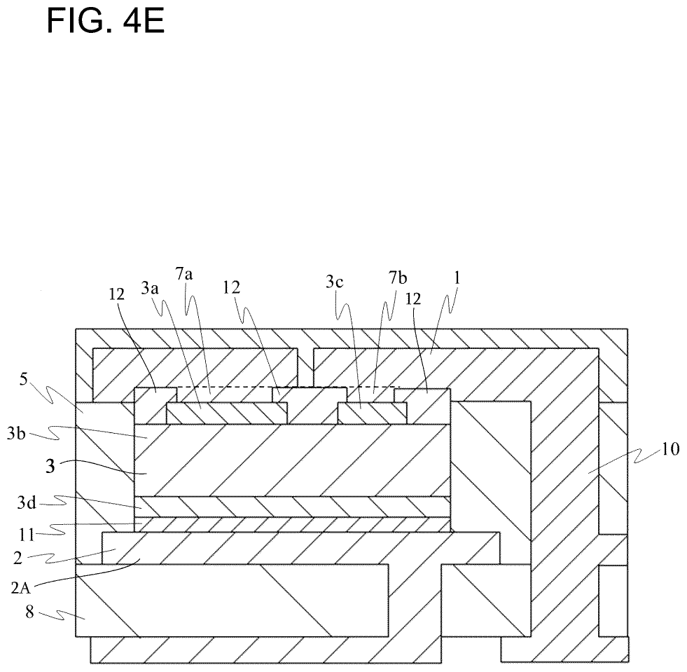

Hereinafter, a specific manufacturing process of the semiconductor device 200 according to one embodiment of the present disclosure will be described in more detail using the schematic sectional views illustrated in FIGS. 4A to 4E. Note that parts of the method of manufacturing the semiconductor device 200 and combinations thereof are also new and useful and are included in the present disclosure.

FIG. 4A is a schematic sectional view of a structural body in which the semiconductor element 3 is disposed on a print substrate configured of the upper copper foil 2a, the base material 8, and the lower copper foil 2b. The base material 8 is configured of an insulating substrate. Examples of a constituent material of the base material 8 include glass, an epoxy resin, a phenol resin, and/or mixtures thereof. Wiring patterns are formed in the upper copper foil 2a and the lower copper foil 2b as needed. In the structural body in FIG. 4A, the semiconductor element 3 is bonded onto the upper copper foil 2a using the conductive adhesive layer 11.

The support substrate 13 is bonded to the semiconductor element 3 on the side of a first surface (the side on which the first electrode 3a and the second electrode 3c are disposed) in the structural body in FIG. 4A via the temporary fixing adhesive layer 15 and the peeling layer 14, thereby obtaining a structural body illustrated in FIG. 4B. It is possible to maintain a state where the semiconductor element on the side of the first surface is not embedded in the insulator 5 even through sealing achieved by molding, which will be described later, by protecting the first electrode 3a and the second electrode 3c in this manner.

Then, the support substrate 13, the peeling layer 14, and the temporary fixing adhesive layer 15 are removed after molding is performed, thereby obtaining a structural body in FIG. 4C similarly to the case of the aforementioned method of manufacturing the semiconductor device 100 in FIG. 1. Then, a hole 10′ for forming a through-hole is formed using a known method such as a laser, thereby obtaining a structural body in FIG. 4D. In the structural body in FIG. 4D, the hole 10′ for forming a through-hole is formed to penetrate through the insulator 5 and reaches the lower copper foil 2b. A known method such as a plating method (an electrolytic plating method or an electroless plating method) is used on the structural body in FIG. 4D to form a metal layer to be used as the first wiring layer 1, patterning for wiring is performed using a known patterning method to form the first wiring layer 1, thereby obtaining a structural body illustrated in FIG. 4E. At this time, burying of a conductive via in the hole 10′ for forming a through-hole is also performed. Description and illustration of subsequent formation and the like of the insulating protective layer will be omitted. In the present disclosure, it is possible to suitably obtain the semiconductor device 200 in which the connection areas of the connecting portions 7a and 7b and the electrodes 3a and 3c are sufficiently secured even by manufacturing the semiconductor device 200 in this manner. Also, it is possible to suitably obtain the semiconductor device 200 in which straight portions of the connecting portions 7a and 7b and straight portions of the electrodes 3a and 3c are parallel or substantially parallel to each other.

Also, the aforementioned semiconductor devices 100 and 200 may be adopted as sub-modules, and a plurality of such submodules may be combined to form a module and be used in the embodiments of the present disclosure.

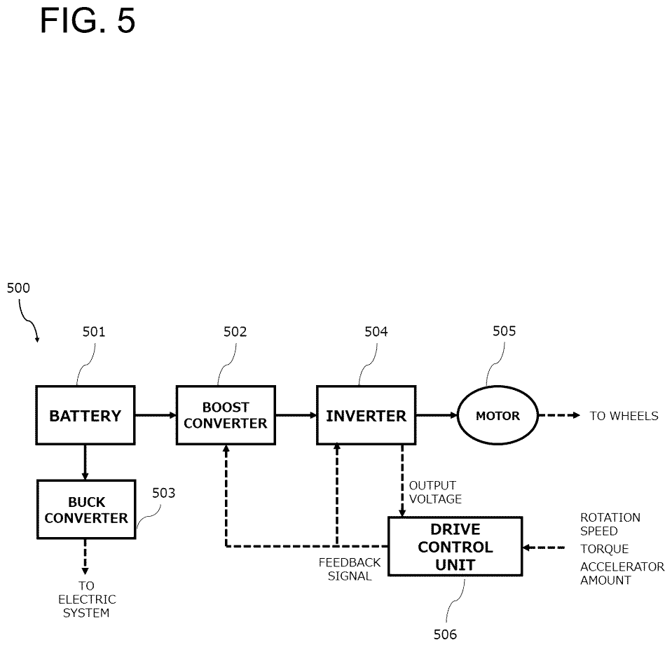

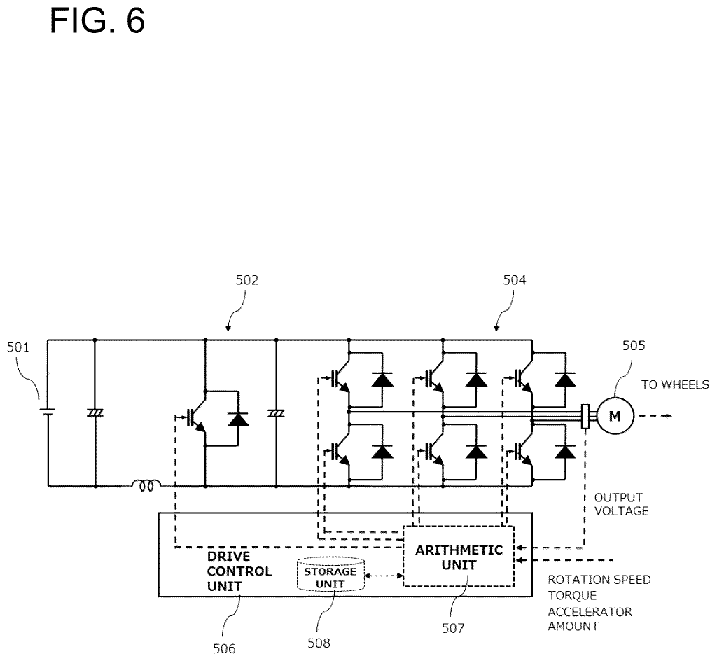

It is possible to apply the aforementioned semiconductor devices 100 and 200 according to the embodiments of the present disclosure to a power conversion apparatus such as an inverter or a converter to cause the semiconductor devices 100 and 200 to exhibit the aforementioned functions. FIG. 5 is a block configuration diagram illustrating an example of a control system 500 using the semiconductor devices 100 and 200 according to the embodiments of the present disclosure, and FIG. 6 is a circuit diagram of the control system 500, which is a control system that is suitable for the mounting in an electric vehicle, in particular.

In order to exhibit the functions described above, the semiconductor film and/or the semiconductor device of the disclosure described above can be applied to a power converter such as an inverter or a converter.

More specifically, it can be applied as a diode incorporated in the inverter or converter, a thyristor, a power transistor, an IGBT (Insulated Gate Bipolar Transistor), a MOSFET (Metal-Oxide-Semiconductor Field Effect Transistor or the like as a switching element.

FIG. 5 is a block diagram illustrating an exemplary control system applying a semiconductor device according to an embodiment of the disclosure, and FIG. 6 is a circuit diagram of the control system particularly suitable for applying to a control system of an electric vehicle.

As shown in FIG. 5, the control system 500 includes a battery (power supply) 501, a boost converter 502, a buck converter 503, an inverter 504, a motor (driving object) 505, a drive control unit 506, which are mounted on an electric vehicle.

The battery 501 consists of, for example, a storage battery such as a nickel hydrogen battery or a lithium-ion battery. The battery 501 can store electric power by charging at the power supply station or regenerating at the time of deceleration, and to output a direct current (DC) voltage required for the operation of the driving system and the electrical system of the electric vehicle.

The boost converter 502 is, for example, a voltage converter in which a chopper circuit is mounted, and can step-up DC voltage of, for example, 200V supplied from the battery 501 to, for example, 650V by switching operations of the chopper circuit. The step-up voltage can be supplied to a traveling system such as a motor.

The buck converter 503 is also a voltage converter in which a chopper circuit is mounted, and can step-down DC voltage of, for example, 200V supplied from the battery 501 to, for example, about 12V. The step-down voltage can be supplied to an electric system including a power window, a power steering, or an electric device mounted on a vehicle.

The inverter 504 converts the DC voltage supplied from the boost converter 502 into three-phase alternating current (AC) voltage by switching operations, and outputs to the motor 505.

The motor 505 is a three-phase AC motor constituting the traveling system of an electric vehicle, and is driven by an AC voltage of the three-phase output from the inverter 504. The rotational driving force is transmitted to the wheels of the electric vehicle via a transmission mechanism (not shown).

On the other hand, actual values such as rotation speed and torque of the wheels, the amount of depression of the accelerator pedal (accelerator amount) are measured from an electric vehicle in cruising by using various sensors (not shown), The signals thus measured are input to the drive control unit 506.

The output voltage value of the inverter 504 is also input to the drive control unit 506 at the same time.

The drive control unit 506 has a function of a controller including an arithmetic unit such as a CPU (Central Processing Unit) and a data storage unit such as a memory, and generates a control signal using the inputted measurement signal and outputs the control signal as a feedback signal to the inverters 504, thereby controlling the switching operation by the switching elements.

The AC voltage supplied to the motor 505 from the inverter 504 is thus corrected instantaneously, and the driving control of the electric vehicle can be executed accurately. Safety and comfortable operation of the electric vehicle is thereby realized.

In addition, it is also possible to control the output voltage to the inverter 504 by providing a feedback signal from the drive control unit 506 to the boost converter 502.

FIG. 6 is a circuit configuration excluding the buck converter 503 in FIG. 5, in other words, a circuit configuration showing a configuration only for driving the motor 505.

As shown in the FIG. 6, the semiconductor device of the disclosure is provided for switching control by, for example, being applied to the boost controller 502 and the inverter 504 as a Schottky barrier diode.

The boost converter 502 performs chopper control by incorporating the semiconductor device into the chopper circuit of the boost converter 502. Similarly, the inverter 504 performs switching control by incorporating the semiconductor device into the switching circuit including an IGBT of the inverter 504.

The current can be stabilized by interposing an inductor (such as a coil) at the output of the battery 501. Also, the voltage can be stabilized by interposing a capacitor (such as an electrolytic capacitor) between each of the battery 501, the boost converter 502, and the inverter 504.

As indicated by a dotted line in FIG. 6, an arithmetic unit 507 including a CPU (Central Processing Unit) and a storage unit 508 including a nonvolatile memory are provided in the drive control unit 506.

Signal input to the drive control unit 506 is given to the arithmetic unit 507, and a feedback signal for each semiconductor element is generated by performing the programmed operation as necessary.

The storage unit 508 temporarily holds the calculation result by the calculation unit 507, stores physical constants and functions necessary for driving control in the form of a table, and outputs the physical constants, functions, and the like to the arithmetic unit 507 as appropriate.

The arithmetic unit 507 and the storage unit 508 can be provided by a known configuration, and the processing capability and the like thereof can be arbitrarily selected.

As shown in FIGS. 5 and 6, a diode and a switching element such as a thyristor, a power transistor, an IGBT, a MOSFET and the like is employed for the switching operation of the boost converter 502, the buck converter 503 and the inverter 504 in the control system 500.

The use of gallium oxide (Ga2O3) specifically corundum-type gallium oxide (α-Ga2O3) as its materials for these semiconductor devices greatly improves switching properties.

Further, extremely outstanding switching performance can be expected and miniaturization and cost reduction of the control system 500 can be realized by applying a semiconductor film or a semiconductor device of the disclosure. That is, each of the boost converter 502, the buck converter 503 and the inverter 504 can be expected to have the benefit of the disclosure, and the effect and the advantages can be expected in any one or combination of the boost converter 502, the buck converter 503 and the inverter 504, or in any one of the boost converter 502, the buck converter 503 and the inverter 504 together with the drive control unit 506.

The control system 500 described above is not only applicable to the control system of an electric vehicle of the semiconductor device of the disclosure, but can be applied to a control system for any applications such as to step-up and step-down the power from a DC power source, or convert the power from a DC to an AC.

It is also possible to use a power source such as a solar cell as a battery.

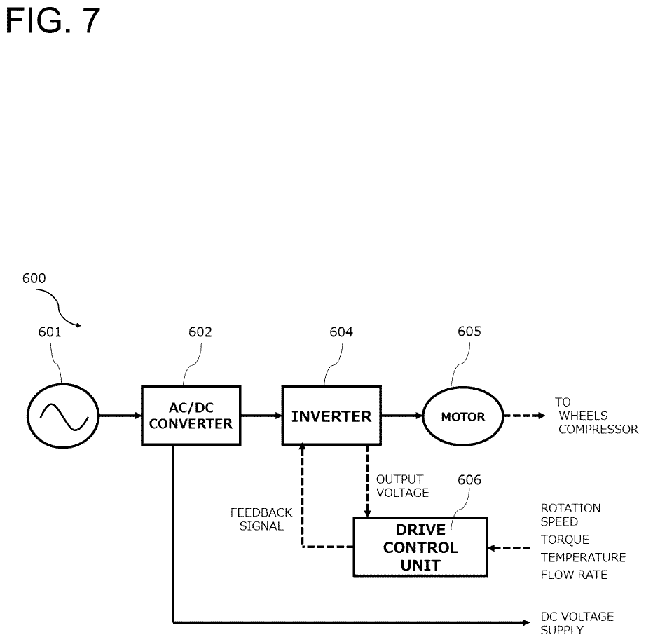

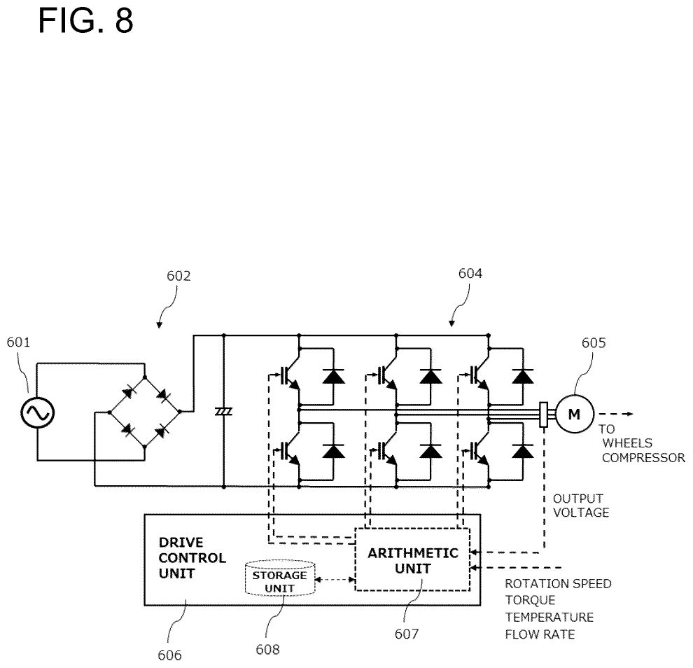

FIG. 7 is a block diagram illustrating another exemplary control system applying a semiconductor device according to an embodiment of the disclosure, and FIG. 8 is a circuit diagram of the control system suitable for applying to infrastructure equipment and home appliances or the like operable by the power from the AC power source.

As shown in FIG. 7, the control system 600 is provided for inputting power supplied from an external, such as a three-phase AC power source (power supply) 601, and includes an AC/DC converter 602, an inverter 604, a motor (driving object) 605 and a drive control unit 606 that can be applied to various devices described later.

The three-phase AC power supply 601 is, for example, a power plant (such as a thermal, hydraulic, geothermal, or nuclear plant) of an electric power company, whose output is supplied as an AC voltage while being downgraded through substations.

Further, the three-phase AC power supply 601 is installed in a building or a neighboring facility in the form of a private power generator or the like for supplying the generated power via a power cable.

The AC/DC converter 602 is a voltage converter for converting AC voltage to DC voltage. The AC/DC converter 602 converts AC voltage of 100V or 200V supplied from the three-phase AC power supply 601 to a predetermined DC voltage.

Specifically, AC voltage is converted by a transformer to a desired, commonly used voltage such as 3.3V, 5V, or 12V.

When the driving object is a motor, conversion to 12V is performed.

It is possible to adopt a single-phase AC power supply in place of the three-phase AC power supply. In this case, same system configuration can be realized if an AC/DC converter of the single-phase input is employed.

The inverter 604 converts the DC voltage supplied from the AC/DC converter 602 into three-phase AC voltage by switching operations and outputs to the motor 605.

Configuration of the motor 605 is variable depending on the control object. It can be a wheel if the control object is a train, can be a pump and various power source if the control objects a factory equipment, can be a three-phase AC motor for driving a compressor or the like if the control object is a home appliance. The motor 605 is driven to rotate by the three-phase AC voltage output from the inverter 604, and transmits the rotational driving force to the driving object (not shown).

There are many kinds of driving objects such as personal computer, LED lighting equipment, video equipment, audio equipment and the like capable of directly supplying a DC voltage output from the AC/DC converter 602. In that case the inverter 604 becomes unnecessary in the control system 600, and a DC voltage from the AC/DC converter 602 is supplied to the driving object directly as shown in FIG. 7.

Here, DC voltage of 3.3V is supplied to personal computers and DC voltage of 5V is supplied to the LED lighting device for example.

On the other hand, rotation speed and torque of the driving object, measured values such as the temperature and flow rate of the peripheral environment of the driving object, for example, is measured using various sensors (not shown), these measured signals are input to the drive control unit 606.

At the same time, the output voltage value of the inverter 604 is also input to the drive control unit 606.

Based on these measured signals, the drive control unit 606 provides a feedback signal to the inverter 604 thereby controls switching operations by the switching element of the inverter 604.

The AC voltage supplied to the motor 605 from the inverter 604 is thus corrected instantaneously, and the operation control of the driving object can be executed accurately. Stable operation of the driving object is thereby realized.

In addition, when the driving object can be driven by a DC voltage, as described above, feedback control of the AC/DC converter 602 is possible in place of feedback control of the inverter 604.

FIG. 8 shows the circuit configuration of FIG. 7.

As shown in FIG. 8, the semiconductor device of the disclosure is provided for switching control by, for example, being applied to the AC/DC converter 602 and the inverter 604 as a Schottky barrier diode.

The AC/DC converter 602 has, for example, a circuit configuration in which Schottky barrier diodes are arranged in a bridge-shaped, to perform a direct-current conversion by converting and rectifying the negative component of the input voltage to a positive voltage.

Schottky barrier diodes can also be applied to a switching circuit in IGBT of the inverter 604 to perform switching control.

The voltage can be stabilized by interposing a capacitor (such as an electrolytic capacitor) between the AC/DC converter 602 and the inverter 604.

As indicated by a dotted line in FIG. 8, an arithmetic unit 607 including a CPU and a storage unit 608 including a nonvolatile memory are provided in the drive control unit 606.

Signal input to the drive control unit 606 is given to the arithmetic unit 607, and a feedback signal for each semiconductor element is generated by performing the programmed operation as necessary.

The storage unit 608 temporarily holds the calculation result by the arithmetic unit 607, stores physical constants and functions necessary for driving control in the form of a table, and outputs the physical constants, functions, and the like to the arithmetic unit 607 as appropriate.

The arithmetic unit 607 and the storage unit 608 can be provided by a known configuration, and the processing capability and the like thereof can be arbitrarily selected.

In such a control system 600, similarly to the control system 500 shown in FIGS. 3 and 4, a diode or a switching element such as a thyristor, a power transistor, an IGBT, a MOSFET or the like is also applied for the purpose of the rectification operation and switching operation of the AC/DC converter 602 and the inverter 604.

Switching performance can be improved by the use of gallium oxide (Ga2O3), particularly corundum-type gallium oxide (α-Ga2O3), as materials for these semiconductor elements.

Further, extremely outstanding switching performance can be expected and miniaturization and cost reduction of the control system 600 can be realized by applying a semiconductor film or a semiconductor device of the disclosure.

That is, each of the AC/DC converter 602 and the inverter 604 can be expected to have the benefit of the disclosure, and the effects and the advantages of the disclosure can be expected in any one or combination of the AC/DC converter 602 and the inverter 604, or in any of the AC/DC converter 602 and the inverter 604 together with the drive control unit 606.

Although the motor 605 has been exemplified in FIGS. 7 and 8, the driving object is not necessarily limited to those that operate mechanically. Many devices that require an AC voltage can be a driving object.

It is possible to apply the control system 600 as long as electric power is obtained from AC power source to drive the driving object. The control system 600 can be applied to the driving control of any electric equipment such as infrastructure equipment (electric power facilities such as buildings and factories, telecommunication facilities, traffic control facilities, water and sewage treatment facilities, system equipment, labor-saving equipment, trains and the like) and home appliances (refrigerators, washing machines, personal computers, LED lighting equipment, video equipment, audio equipment and the like).

Hereinafter, supplements of the aforementioned embodiments will be given below. Hereinafter, various aspects of the present disclosure will be collectively described as supplements.

### [Structure 1]

A semiconductor device including: a first wiring layer; a holding layer; a semiconductor element that is disposed between the first wiring layer and the holding layer and includes at least a semiconductor layer and a first electrode disposed on a first surface of the semiconductor layer; an insulator in which at least a part of the semiconductor element is embedded; and a first connecting portion that electrically connects the first wiring layer and the first electrode, wherein a connection area between the first connecting portion and the first electrode occupies 45% or more of an area of an exposed part of the first electrode.

### [Structure 2]

The semiconductor device according to [Structure 1], wherein in a plan view, an outer periphery of the first electrode includes a first straight portion, an outer periphery of the first connecting portion includes a second straight portion, and the first straight portion and the second straight portion are parallel or substantially parallel to each other.

### [Structure 3]

The semiconductor device according to [Structure 1] or [Structure 2], wherein the first connecting portion is in contact with the exposed part of the first electrode, and a shortest distance between the first connecting portion and an end portion of the exposed part is less than 50 μm in a plan view.

### [Structure 4]

The semiconductor device according to any one of [Structure 1] to [Structure 3], wherein the holding layer includes a projecting portion that is located immediately below the semiconductor element and is at least partially buried in the insulator.

### [Structure 5]

The semiconductor device according to any one of [Structure 1] to [Structure 4], wherein the connection area of the first connecting portion and the first electrode occupies 60% or more of the area of the exposed part of the first electrode.

### [Structure 6]

A semiconductor device including: a first wiring layer; a holding layer; a semiconductor element that is disposed between the first wiring layer and the holding layer and includes at least a semiconductor layer and a first electrode disposed on a first surface of the semiconductor layer; an insulator in which at least a part of the semiconductor element is embedded; and a first connecting portion that electrically connects the first wiring layer and the first electrode, wherein in a plan view, an outer periphery of the first electrode includes a first straight portion, an outer periphery of the first connecting portion includes a second straight portion, and the first straight portion and the second straight portion are parallel or substantially parallel to each other.

### [Structure 7]

The semiconductor device according to [Structure 6], wherein a distance between the first straight portion and the second straight portion is less than 50 μm in a plan view.

### [Structure 8]

The semiconductor device according to [Structure 6] or [Structure 7], wherein a second electrode with an area that is different from an area of the first electrode is disposed on the first surface of the semiconductor layer, the second electrode and the first wiring layer are electrically connected via a second connecting portion, and in a plan view, an outer periphery of the second electrode includes a third straight portion, an outer periphery of the second connecting portion includes a fourth straight portion, and the third straight portion and the fourth straight portion are parallel or substantially parallel to each other.

### [Structure 9]

The semiconductor device according to any one of [Structure 6] to [Structure 8], wherein the semiconductor element includes a second surface on a side opposite to the first surface of the semiconductor layer, a third electrode is disposed on the second surface, the holding layer includes a second wiring layer, the second wiring layer and the third electrode are electrically connected via a third connecting portion, and in a plan view, an outer periphery of the third electrode includes a fifth straight portion, an outer periphery of the third connecting portion includes a sixth straight portion, and the fifth straight portion and the sixth straight portion are parallel or substantially parallel to each other.

### [Structure 10]

The semiconductor device according to any one of [Structure 6] to [Structure 9], wherein in a plan view, the outer periphery of the first electrode has a polygonal shape, and the outer periphery of the first connecting portion has a polygonal shape.

### [Structure 11]

The semiconductor device according to [Structure 10], wherein the outer periphery of the first electrode and the outer periphery of the first connecting portion have similar shapes or substantially similar shapes.

### [Structure 12]

A semiconductor device including: a first wiring layer; a holding layer; a semiconductor element that is disposed between the first wiring layer and the holding layer and includes a semiconductor layer and a first electrode disposed on a first surface of the semiconductor layer; and a first connecting portion that is in contact with an exposed part of the first electrode and electrically connects the first wiring layer and the first electrode, wherein in a plan view, a shortest distance between the first connecting portion and an end portion of the exposed part is less than 50 μm.

### [Structure 13]

The semiconductor device according to [Structure 12], wherein the shortest distance between the first connecting portion and the end portion of the exposed part is less than 30 μm in a plan view.

### [Structure 14]

The semiconductor device according to [Structure 12] or [Structure 13], including: an insulating film that covers at least an outer end portion of the first electrode and includes an opening portion, wherein the end portion of the exposed part is an end portion of the opening portion.

### [Structure 15]

The semiconductor device according to any one of [Structure 12] to [Structure 14], wherein a second electrode with an area that is different from an area of the first electrode is disposed on the first surface of the semiconductor layer, the second electrode and the first wiring layer are electrically connected via a second connecting portion, and in a plan view, a shortest distance between the second connecting portion and an end portion of an exposed part of the second electrode is less than 50 μm.

### [Structure 16]

The semiconductor device according to any one of [Structure 12] to [Structure 15], wherein the semiconductor element includes a second surface on a side opposite to the first surface of the semiconductor layer, a third electrode is disposed on the second surface, the holding layer includes a second wiring layer, the second wiring layer and the third electrode are electrically connected via a third connecting portion, and in a plan view, a shortest distance between the third connecting portion and an end portion of an exposed part of the third electrode is less than 50 μm.

### [Structure 17]

A semiconductor device including: a first wiring layer; a holding layer; a semiconductor element that is disposed between the first wiring layer and the holding layer; and an insulator in which at least a part of the semiconductor element is embedded, wherein the holding layer includes a projecting portion that is located immediately below the semiconductor element and is at least partially buried in the insulator.

### [Structure 18]

The semiconductor device according to any one of [Structure 1] to [Structure 17], wherein the first wiring layer is an outermost wiring layer.

### [Structure 19]

The semiconductor device according to any one of [Structure 1] to [Structure 18], wherein the first wiring layer is in contact with the insulator.

### [Structure 20]

The semiconductor device according to any one of [Structure 1] to [Structure 13], [Structure 15], [Structure 16], including: an insulating film that covers at least an outer end portion of the first electrode and includes an opening portion.

### [Structure 21]

The semiconductor device according to [Structure 20], wherein an interface between the first wiring layer and the insulating film is located further upward than an interface between the first wiring layer and the insulator in a stacking direction.

### [Structure 22]

The semiconductor device according to any one of [Structure 1] to [Structure 16], wherein the first connecting portion and the first wiring layer are integrally formed.

### [Structure 23]

The semiconductor device according to any one of [Structure 1] to [Structure 16], wherein an interface between the first connecting portion and the first electrode and an interface between the first wiring layer and the insulator are located in a same plane or a substantially same plane.

### [Structure 24]

The semiconductor device according to any one of [Structure 1] to [Structure 16], wherein an upper surface of the insulator and an upper surface of the first electrode are located in a same plane or a substantially same plane.

### [Structure 25]

The semiconductor device according to any one of [Structure 1] to [Structure 16], wherein the first connecting portion is made of a single connecting body.

### [Structure 26]

The semiconductor device according to any one of [Structure 1] to [Structure 16], wherein the first connecting portion includes a plurality of connecting bodies with mutually different areas in a plan view.

### [Structure 27]

The semiconductor device according to any one of [Structure 1] to [Structure 7], [Structure 9] to [Structure 14] [Structure 16], wherein a second electrode with an area that is different from an area of the first electrode is disposed on the first surface of the semiconductor layer, and the second electrode and the first wiring layer are electrically connected via a second connecting portion.

### [Structure 28]

The semiconductor device according to [Structure 27], wherein a connection area between the second connecting portion and the second electrode occupies 45% or more of an area of an exposed part of the second electrode.

### [Structure 29]

The semiconductor device according to [Structure 27] or [Structure 28], wherein the first connecting portion includes one connecting body or two or more connecting bodies, and the second connecting portion includes one connecting body or two or more connecting bodies with an area that is different from an area of the one connecting body or two or more connecting bodies of the first connecting portion in a plan view.

### [Structure 30]

The semiconductor device according to any one of [Structure 1] to [Structure 8], [Structure 10] to [Structure 16], wherein the semiconductor element includes a second surface on a side opposite to the first surface of the semiconductor layer, and a third electrode is disposed on the second surface.

### [Structure 31]

The semiconductor device according to [Structure 30], wherein the holding layer includes a second wiring layer, and the second wiring layer and the third electrode are electrically connected via a third connecting portion.

### [Structure 32]

The semiconductor device according to [Structure 31], wherein a connection area between the third connecting portion and the third electrode occupies 45% or more of an area of an exposed part of the third electrode.

### [Structure 33]

The semiconductor device according to [Structure 31] or [Structure 32], wherein the third connecting portion and the second wiring layer are integrally formed.

### [Structure 34]

A power conversion apparatus that uses the semiconductor device according to any one of [Structure 1] to [Structure 33].

### [Structure 35]

A control system that uses the semiconductor device according to any one of

### [Structure 1] to [Structure 33].

### REFERENCE SIGNS LIST

1 First wiring layer (upper wiring layer)
2 Second wiring layer (lower wiring layer)
2A Holding layer
2a Upper copper foil
2b Lower copper foil
2c Through-hole
3 Semiconductor element
3a First electrode (source electrode, emitter electrode)
3b Semiconductor layer
3c Second electrode (gate electrode)
3d Third electrode (drain electrode, collector electrode)
5 Insulator
7a First connecting portion
7b Second connecting portion
7c Third connecting portion (projecting portion)
8 Base material
9a Insulating protective layer
9b Insulating protective layer
10 Metal block (through-hole)
11 Adhesive layer (conductive adhesive layer, projecting portion)
12 Insulating film
13 Support substrate
14 Peeling layer
15 Temporary fixing adhesive layer
16 Mold release film
17 Resist
18 Temporary fixing adhesive layer
19 Peeling layer
20 Support substrate
21a First straight portion
22a Second straight portion
23a Third straight portion
24a Fourth straight portion
100 Semiconductor device
200 Semiconductor device
500 Control system
501 Battery (power source)
502 Boost converter
503 Step-down converter
504 Inverter
505 Motor (drive target)
506 Drive Control unit
507 Calculation unit
508 Storage unit
600 Control system
601 Three-phase alternating current power source (power source)
602 AC/DC converter
604 Inverter
605 Motor (drive target)
606 Drive control unit
607 Calculation unit
608 Storage unit

What is claimed is:

1. A semiconductor device comprising:
a first wiring layer;
a holding layer;
a semiconductor element that is disposed between the first wiring layer and the holding layer and includes at least a semiconductor layer and a first electrode disposed on a first surface of the semiconductor layer;
an insulator in which at least a part of the semiconductor element is embedded; and
a first connecting portion that electrically connects the first wiring layer and the first electrode,
wherein a connection area between the first connecting portion and the first electrode occupies 45% or more of an area of an exposed part of the first electrode.

2. The semiconductor device according to claim 1, wherein in a plan view, an outer periphery of the first electrode includes a first straight portion, an outer periphery of the first connecting portion includes a second straight portion, and the first straight portion and the second straight portion are parallel or substantially parallel to each other.

3. The semiconductor device according to claim 1,
wherein the first connecting portion is in contact with the exposed part of the first electrode, and
a shortest distance between the first connecting portion and an end portion of the exposed part is less than 50 μm in a plan view.

4. The semiconductor device according to claim 1, wherein the holding layer includes a projecting portion that is located immediately below the semiconductor element and is at least partially buried in the insulator.

5. The semiconductor device according to claim 1, wherein the connection area of the first connecting portion and the first electrode occupies 60% or more of the area of the exposed part of the first electrode.

6. A semiconductor device comprising:
a first wiring layer;
a holding layer;
a semiconductor element that is disposed between the first wiring layer and the holding layer and includes at least a semiconductor layer and a first electrode disposed on a first surface of the semiconductor layer;
an insulator in which at least a part of the semiconductor element is embedded; and
a first connecting portion that electrically connects the first wiring layer and the first electrode,
wherein in a plan view, an outer periphery of the first electrode includes a first straight portion, an outer periphery of the first connecting portion includes a second straight portion, and the first straight portion and the second straight portion are parallel or substantially parallel to each other.

7. The semiconductor device according to claim 6, wherein a distance between the first straight portion and the second straight portion is less than 50 μm in a plan view.

8. The semiconductor device according to claim 6,
wherein a second electrode with an area that is different from an area of the first electrode is disposed on the first surface of the semiconductor layer, the second electrode and the first wiring layer are electrically connected via a second connecting portion, and in a plan view, an outer periphery of the second electrode includes a third straight portion, an outer periphery of the second connecting portion includes a fourth straight portion, and the third straight portion and the fourth straight portion are parallel or substantially parallel to each other.

9. The semiconductor device according to claim 6, wherein the semiconductor element includes a second surface on a side opposite to the first surface of the semiconductor layer, a third electrode is disposed on the second surface, the holding layer includes a second wiring layer, the second wiring layer and the third electrode are electrically connected via a third connecting portion, and in a plan view, an outer periphery of the third electrode includes a fifth straight portion, an outer periphery of the third connecting portion includes a sixth straight portion, and the fifth straight portion and the sixth straight portion are parallel or substantially parallel to each other.

10. The semiconductor device according to claim 6, wherein in a plan view, the outer periphery of the first electrode has a polygonal shape, and the outer periphery of the first connecting portion has a polygonal shape.

11. The semiconductor device according to claim 10, wherein the outer periphery of the first electrode and the outer periphery of the first connecting portion have similar shapes or substantially similar shapes.

12. A semiconductor device comprising:
a first wiring layer;
a holding layer;
a semiconductor element that is disposed between the first wiring layer and the holding layer and includes a semiconductor layer and a first electrode disposed on a first surface of the semiconductor layer; and
a first connecting portion that is in contact with an exposed part of the first electrode and electrically connects the first wiring layer and the first electrode,
wherein in a plan view, a shortest distance between the first connecting portion and an end portion of the exposed part is less than 50 μm.

13. The semiconductor device according to claim 12, wherein the shortest distance between the first connecting portion and the end portion of the exposed part is less than 30 μm in a plan view.

14. The semiconductor device according to claim 12, comprising:
an insulating film that covers at least an outer end portion of the first electrode and includes an opening portion,
wherein the end portion of the exposed part is an end portion of the opening portion.

15. The semiconductor device according to claim 12, wherein a second electrode with an area that is different from an area of the first electrode is disposed on the first surface of the semiconductor layer, the second electrode and the first wiring layer are electrically connected via a second connecting portion, and in a plan view, a shortest distance between the second connecting portion and an end portion of an exposed part of the second electrode is less than 50 μm.

16. The semiconductor device according to claim 12, wherein the semiconductor element includes a second surface on a side opposite to the first surface of the semiconductor layer, a third electrode is disposed on the second surface, the holding layer includes a second wiring layer, the second wiring layer and the third electrode are electrically connected via a third connecting portion, and in a plan view, a shortest distance between the third connecting portion and an end portion of an exposed part of the third electrode is less than 50 μm.

17. A semiconductor device comprising:
a first wiring layer;
a holding layer;
a semiconductor element that is disposed between the first wiring layer and the holding layer; and
an insulator in which at least a part of the semiconductor element is embedded,
wherein the holding layer includes a projecting portion that is located immediately below the semiconductor element and is at least partially buried in the insulator.

18. The semiconductor device according to claim 1, wherein the first wiring layer is an outermost wiring layer.

19. The semiconductor device according to claim 1, wherein the first wiring layer is in contact with the insulator.

20. The semiconductor device according to claim 1, comprising:
an insulating film that covers at least an outer end portion of the first electrode and includes an opening portion.

21. The semiconductor device according to claim 20, wherein an interface between the first wiring layer and the insulating film is located further upward than an interface between the first wiring layer and the insulator in a stacking direction.

22. The semiconductor device according to claim 1, wherein the first connecting portion and the first wiring layer are integrally formed.

23. The semiconductor device according to claim 1, wherein an interface between the first connecting portion and the first electrode and an interface between the first wiring layer and the insulator are located in a same plane or a substantially same plane.

24. The semiconductor device according to claim 1, wherein an upper surface of the insulator and an upper surface of the first electrode are located in a same plane or a substantially same plane.

25. The semiconductor device according to claim 1, wherein the first connecting portion is made of a single connecting body.

26. The semiconductor device according to claim 1, wherein the first connecting portion includes a plurality of connecting bodies with mutually different areas in a plan view.

27. The semiconductor device according to claim 1 wherein a second electrode with an area that is different from an area of the first electrode is disposed on the first surface of the semiconductor layer, and the second electrode and the first wiring layer are electrically connected via a second connecting portion.

28. The semiconductor device according to claim 27, wherein a connection area between the second connecting portion and the second electrode occupies 45% or more of an area of an exposed part of the second electrode.

29. The semiconductor device according to claim 27, wherein the first connecting portion includes one connecting body or two or more connecting bodies, and the second connecting portion includes one connecting body or two or more connecting bodies with an area that is different from an area of the one connecting body or two or more connecting bodies of the first connecting portion in a plan view.

30. The semiconductor device according to claim 1, wherein the semiconductor element includes a second surface on a side opposite to the first surface of the semiconductor layer, and a third electrode is disposed on the second surface.

31. The semiconductor device according to claim 30, wherein the holding layer includes a second wiring layer, and the second wiring layer and the third electrode are electrically connected via a third connecting portion.

32. The semiconductor device according to claim 31, wherein a connection area between the third connecting portion and the third electrode occupies 45% or more of an area of an exposed part of the third electrode.

33. The semiconductor device according to claim 31, wherein the third connecting portion and the second wiring layer are integrally formed.

34. A power conversion apparatus that uses the semiconductor device according to claim 1.

35. A control system that uses the semiconductor device according to claim 1.
